(19) United States
(12) Patent Application Publication
(10) Pub. No.: US 2026/0052861 A1
(43) Pub. Date: Feb. 19, 2026

(54) DISPLAY DEVICE AND ELECTRONIC DEVICE INCLUDING THE DISPLAY DEVICE

(71) Applicant: Samsung Display Co., Ltd., Yongin-si (KR)

(72) Inventors: Sunkwun Son, Yongin-si (KR); Junhyun Park, Yongin-si (KR); Nahyeon Cha, Yongin-si (KR)

(21) Appl. No.: 19/300,352

(22) Filed: Aug. 14, 2025

(30) Foreign Application Priority Data
Aug. 16, 2024 (KR) 10-2024-0110014

(51) Int. Cl. H10K 59/131

(52) U.S. Cl. CPC H10K 59/131

(57) ABSTRACT

A display device includes a first pixel circuit including a first-first pixel circuit and a first-second pixel circuit arranged along a first direction on a substrate, a first-1 gate line extending in the first direction and electrically connected to the first-1 pixel circuit, a first-2 gate line extending in the first direction and electrically connected to the first-2 pixel circuit, and a reference voltage line including a horizontal reference voltage line extending in the first direction and a vertical reference voltage line protruding in a second direction intersecting the first direction from the horizontal reference voltage line; and the first-1 pixel circuit and the first-2 pixel circuit are arranged with the vertical reference voltage line interposed therebetween.

### CROSS-REFERENCE TO RELATED APPLICATION

The present application claims priority to and the benefit of Korean Patent Application No. 10-2024-0110014, filed on Aug. 16, 2024, in the Korean Intellectual Property Office, the entire disclosure of which is incorporated by reference herein.

### BACKGROUND

### 1. Field

One or more embodiments relate to a display device.

### 2. Description of the Related Art

A display device visually displays image data. The display device may provide images using light-emitting diodes. Display devices are becoming more diverse in use, and various designs have been attempted to improve the quality of display devices.

### SUMMARY

One or more embodiments include a display device.

Additional aspects will be set forth in part in the description which follows and, in part, will be apparent from the description, or may be learned by practice of embodiments of the present disclosure.

According to one or more embodiments, a display device includes a first pixel circuit including a first-1 pixel circuit and a first-2 pixel circuit arranged along a first direction on a substrate, a first-1 gate line extending in the first direction and electrically connected to the first-1 pixel circuit, a first-2 gate line extending in the first direction and electrically connected to the first-2 pixel circuit and a reference voltage line including a horizontal reference voltage line extending in the first direction and a vertical reference voltage line protruding in a second direction intersecting the first direction from the horizontal reference voltage line, wherein the first-1 pixel circuit and the first-2 pixel circuit are arranged with the vertical reference voltage line interposed therebetween.

According to one or more embodiments, the first pixel circuit may further include a first light-emitting diode electrically connected to the first pixel circuit.

According to one or more embodiments, the first light-emitting diode may be arranged along the first direction and including a first-1 light-emitting diode electrically connected to the first-1 pixel circuit and a first-2 light-emitting diode electrically connected to the first-2 pixel circuit.

According to one or more embodiments, the first-1 light-emitting diode and the first-2 light-emitting diode may be configured to emit light of a same color.

According to one or more embodiments, the display device may further include a first data line on the substrate, extending in the second direction, and overlapping the vertical reference voltage line.

According to one or more embodiments, the first-1 pixel circuit and the first-2 pixel circuit may be arranged with the first data line interposed therebetween.

According to one or more embodiments, the display device may further include a second pixel circuit, which is arranged adjacent to the first pixel circuit in the first direction and includes a second-1 pixel circuit and a second-2 pixel circuit arranged along the first direction and the second-1 pixel circuit and the second-2 pixel circuit may be arranged with the vertical reference voltage line interposed therebetween.

According to one or more embodiments, the first-1 gate line may be electrically connected to the second-1 pixel circuit, and the first-2 gate line may be electrically connected to the second-2 pixel circuit.

According to one or more embodiments, the display device may further include a second light-emitting diode electrically connected to the second pixel circuit.

According to one or more embodiments, the first light-emitting diode and the second light-emitting diode may be configured to emit light of different colors.

According to one or more embodiments, the second light-emitting diode may include a second-1 light-emitting diode electrically connected to the second-1 pixel circuit and a second-2 light-emitting diode electrically connected to the second-2 pixel circuit, which are arranged along the first direction.

According to one or more embodiments, the second-1 light-emitting diode and the second-2 light-emitting diode may be configured to emit light of a same color.

According to one or more embodiments, the display device may further include a second data line on the substrate, extending in the second direction, and overlapping the vertical reference voltage line.

According to one or more embodiments, the second-1 pixel circuit and the second-2 pixel circuit may be arranged with the second data line interposed therebetween.

According to one or more embodiments, the display device may further include a third pixel circuit, which is arranged adjacent to the second pixel circuit in the first direction and includes a third-1 pixel circuit and a third-2 pixel circuit arranged along the first direction, wherein the third-1 pixel circuit and the third-2 pixel circuit may be arranged with the vertical reference voltage line interposed therebetween.

According to one or more embodiments, the first-1 gate line may be electrically connected to the third-2 pixel circuit, and the first-2 line may be electrically connected to the third-1 pixel circuit.

According to one or more embodiments, the display device may further include a third light-emitting diode electrically connected to the third pixel circuit wherein, the third light-emitting diode is arranged along the first direction and may include a third-1 light-emitting diode electrically connected to the third-1 pixel circuit and a third-2 light-emitting diode electrically connected to the third-2 pixel circuit.

According to one or more embodiments, the third-1 light-emitting diode and the third-2 light-emitting diode may be configured to emit light of the same color.

According to one or more embodiments, the first light-emitting diode, the second light-emitting diode, and the third light-emitting diode may be configured to emit light of different colors.

According to one or more embodiments, the display device may further include a third data line the substrate, extending in the second direction, and overlapping the vertical reference voltage line.

According to one or more embodiments, the third-1 pixel circuit and the third-2 pixel circuit may be arranged with the third data line interposed therebetween. According to one or more embodiments, an electronic device including a display device, the display device including: a first pixel circuit including a first-1 pixel circuit and a first-2 pixel circuit arranged along a first direction on a substrate; a first-1 gate line extending in the first direction and electrically connected to the first-1 pixel circuit; a first-2 gate line extending in the first direction and electrically connected to the first-2 pixel circuit; and a reference voltage line including a horizontal reference voltage line extending in the first direction and a vertical reference voltage line protruding, from the horizontal reference voltage line, in a second direction intersecting the first direction, wherein the first-1 pixel circuit and the first-2 pixel circuit are arranged with the vertical reference voltage line interposed therebetween.

### BRIEF DESCRIPTION OF THE DRAWINGS

Above and other aspects and features of embodiments of the present disclosure will be more apparent from the following description taken in conjunction with the accompanying drawings, in which:

FIG. 1 is a schematic plan view of a display device according to one or more embodiments;

FIG. 2 is a schematic block diagram of a display device according to one or more embodiments;

FIG. 3 is a schematic equivalent circuit diagram of a light-emitting diode, which is a light-emitting element corresponding to one pixel of a display device, and a pixel circuit electrically connected to the light-emitting diode, according to one or more embodiments;

FIG. 4 is a schematic cross-sectional view of a portion of a display device according to one or more embodiments;

FIG. 5 is a schematic plan view of a portion of wires arranged in a display area of a display device according to one or more embodiments; and

FIGS. 6-12 are plan views showing a process of forming a pixel circuit included in a display device according to one or more embodiments.

### DETAILED DESCRIPTION

As the present disclosure allows for various changes and numerous embodiments, particular embodiments will be illustrated in the drawings and described in detail in the written description. The attached drawings for illustrating embodiments of the present disclosure are referred to in order to gain a sufficient understanding of the present disclosure, the merits thereof, and the objectives accomplished by the implementation of the present disclosure. The present disclosure may, however, be embodied in many different forms and should not be construed as being limited to the embodiments set forth herein.

Hereinafter, the present disclosure will be described in detail by discussing embodiments of the present disclosure with reference to the attached drawings. Like reference numerals in the drawings denote like elements, and thus their description will be omitted.

In the following embodiments, while such terms as “first,” “second,” etc., may be used to describe various elements, such elements must not be limited to the above terms.

In the following embodiments, an expression used in the singular encompasses the expression of the plural, unless it has a clearly different meaning in the context.

In the following embodiments, it is to be understood that the terms such as “including” and “having” are intended to indicate the existence of the features, or elements disclosed in the present disclosure, and are not intended to preclude the possibility that one or more other features or elements may exist or may be added.

It will be understood that when a layer, region, or element is referred to as being formed on another layer, region, or element, it can be directly or indirectly formed on the other layer, region, or element. That is, for example, intervening layers, regions, or elements may be present.

Sizes of elements in the drawings may be exaggerated for convenience of explanation. In other words, because sizes and thicknesses of components in the drawings are arbitrarily illustrated for convenience of explanation, the following embodiments are not limited thereto.

When a certain embodiment may be implemented differently, a specific process order may be performed differently from the described order. For example, two consecutively described processes may be performed substantially at the same time or performed in an order opposite to the described order.

In the present disclosure, “A and/or B” may include “A,” “B,” or “A and B.” Also, “at least one of A and B” may indicate A, B, or A and B.

It will be understood that when a layer, region, or component is referred to as being connected to another layer, region, or component, it can be directly or indirectly connected to the other layer, region, or component. That is, for example, intervening layers, regions, or components may be present. For example, it will be understood that when a layer, region, or component is referred to as being electrically connected to another layer, region, or component, it can be directly or indirectly electrically connected to the other layer, region, or component. That is, for example, intervening layers, regions, or components may be present.

The x-axis, the y-axis, and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure will be described in detail with reference to the accompanying drawings.

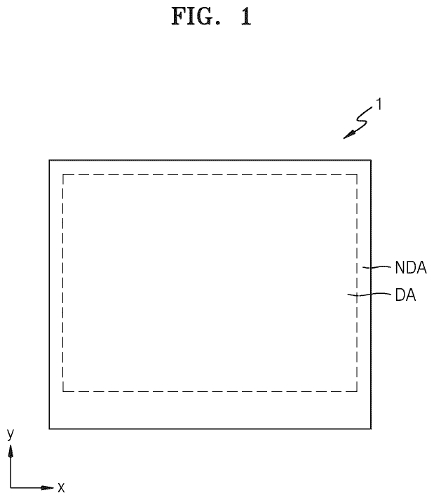

FIG. 1 is a plan view schematically showing a display device 1 according to one or more embodiments.

Referring to FIG. 1, the display device 1 may include a display area DA displaying an image and a non-display area NDA outside the display area DA. The display area DA may be entirely surrounded by the non-display area NDA along an edge or a periphery of the display area DA.

In a plan view, the display area DA may have a rectangular shape. In one or more other embodiments, the display area DA may have a polygonal shape such as a triangular, pentagonal, or hexagonal shape, a circular shape, an elliptical shape, an atypical shape, or the like. A corner of an edge of the display area DA may be rounded.

The display device 1 of FIG. 1 may be a device for displaying a moving image or a still image and may be used in portable electronic devices such as mobile phones, laptop computers, tablet personal computers (PCs), smart phones, mobile communication terminals, electronic notebooks, electronic books, portable multimedia players (PMPs), navigation devices, or ultra mobile PCs (UMPCs). Alternatively, the display device 1 may be used in televisions, monitors, billboards, and electronic devices for Internet of Things (IoT) or may be used in wearable electronic devices such as smart watches, watch phones, glasses-type displays, and head-mounted displays (HMDs). Also, the display device 1 according to one or more embodiments may be applied to a center information display (CID) arranged at a vehicle's instrument panel or a vehicle's center fascia or dashboard, a room mirror display replacing a vehicle's side mirror, or a display electronic device arranged at a rear side of a vehicle's front seat as entertainment for a vehicle's rear seat.

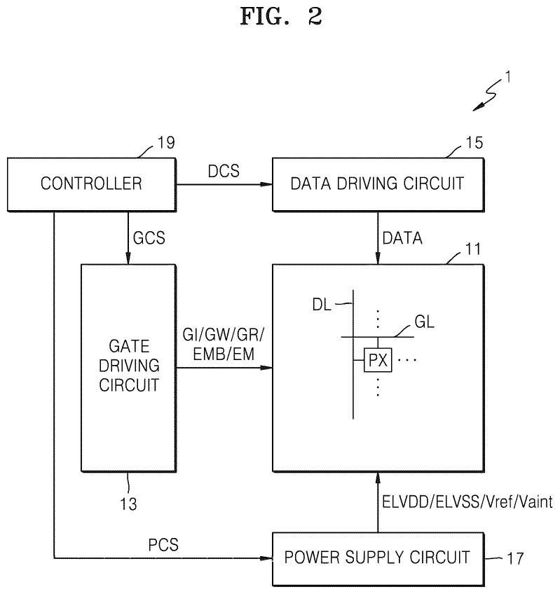

FIG. 2 is a block diagram schematically showing the display device 1 according to one or more embodiments.

Referring to FIGS. 1 and 2, the display device 1 according to one or more embodiments may include a pixel unit 11, a gate driving circuit 13, a data driving circuit 15, a power supply circuit 17, and a controller 19.

The pixel unit 11 may include a plurality of pixels PX arranged in the display area DA (see FIG. 1). The plurality of pixels PX may be arranged in various forms such as a stripe arrangement, a PENTILE® arrangement (diamond arrangement), and a mosaic arrangement to implement an image. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. Each of the plurality of pixels PX may include a display element (e.g., a light emitting diode), and the display element may be electrically connected to a pixel circuit. The plurality of pixels PX may represent an image by using light emitted from a display element corresponding to each of the plurality of pixels PX. The pixel circuit may be electrically connected to a gate line GL and a data line DL and may include a plurality of transistors and at least one capacitor.

Various conductive lines for transmitting electrical signals to be applied to the display area DA (see FIG. 1), peripheral circuits electrically connected to pixel circuits, and/or pads to which a printed circuit board (PCB) or a driver IC chip is attached may be located in the non-display area NDA (see FIG. 1). For example, the gate driving circuit 13, the data driving circuit 15, the power supply circuit 17, and the controller 19 may be provided in the non-display area NDA (see FIG. 1).

The gate driving circuit 13 may be electrically connected to a plurality of gate lines GL, may generate a gate signal in response to a control signal GCS from the controller 19, and may sequentially supply the gate signal to the gate lines GL. The gate signal may be a gate control signal for controlling turn-on and turn-off of the transistor electrically connected to the gate line GL. The gate signal may be a square wave signal including an on voltage at which the transistor may be turned on and an off voltage at which the transistor may be turned off. In one or more embodiments, the on voltage may be a high-level voltage (first-level voltage) or a low-level voltage (second-level voltage).

FIG. 2 illustrates that a pixel circuit corresponding to a pixel PX is connected to the gate line GL. However, this is merely an example and a pixel circuit corresponding to a pixel PX may be connected to two or more gate lines and the gate driving circuit 13 may supply, to the corresponding gate lines, two or more gate signals with different timings when an on voltage is applied. For example, the pixel circuit may be connected to first to fifth gate lines, and the gate driving circuit 13 may apply a first gate signal GW, a second gate signal GR, a third gate signal EM, a fourth gate signal GI, and a fifth gate signal EMB to the first gate line, the second gate line, the third gate line, the fourth gate line, and the fifth gate line respectively. The third gate signal EM may be an emission control signal for controlling turn-on and turn-off of the transistor whose gate is connected to the third gate line.

The data driving circuit 15 may be connected to a plurality of data lines DL and may supply a data signal to the data lines DL in response to a control signal DCS from the controller 19. The data signal supplied to the data line DL may be supplied to the pixel circuit. The data driving circuit 15 may convert input image data with gradation input from the controller 19, into a data signal in the form of a voltage or current.

The power supply circuit 17 may generate voltages necessary for driving the pixel PX, in response to a control signal PCS from the controller 19. The power supply circuit 17 may generate a driving voltage ELVDD and a common voltage ELVSS and supply the same to the pixels PX. The driving voltage ELVDD may be a high-level voltage provided to a first electrode (pixel electrode or anode) of the display element included in the pixel PX. The common voltage ELVSS may be a low-level voltage provided to a second electrode (opposite electrode or cathode) of the display element included in the pixel PX. The power supply circuit 17 may generate a reference voltage Vref and a first initialization voltage Vaint and supply the same to the pixels PX.

The voltage level of the driving voltage ELVDD may be higher than the voltage level of the common voltage ELVSS. The voltage level of the reference voltage Vref may be lower than the voltage level of the driving voltage ELVDD. The voltage level of the first initialization voltage Vaint may be equal to or higher than the voltage level of the common voltage ELVSS.

The controller 19 may generate control signals GCS, DCS, and PCS based on signals input from outside and supply the same to the gate driving circuit 13, the data driving circuit 15, and the power supply circuit 17. The control signal GCS output to the gate driving circuit 13 may include a plurality of clock signals and a gate start signal. The control signal DCS output to the data driving circuit 15 may include a source start signal and clock signals.

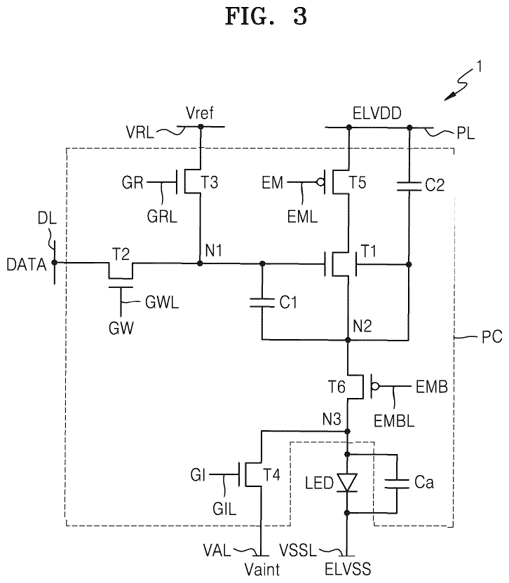

FIG. 3 is a schematic equivalent circuit diagram of a light-emitting diode LED, which is a light-emitting element corresponding to one pixel of the display device 1 according to one or more embodiments, and the pixel circuit PC electrically connected to the light-emitting diode LED

The pixel circuit PC may be electrically connected to a first gate line GWL configured to transmit a first gate signal GW, a second gate line GRL configured to transmit a second gate signal GR, a third gate line EML configured to transmit a third gate signal EM, a fourth gate line GIL configured to transmit a fourth gate signal GI, a fifth gate line EMBL configured to transmit a fifth gate signal EMB, and a data line DL configured to transmit a data signal DATA. Because the light emission of a light emitting diode LED is controlled by the third gate signal EM and the fifth gate signal EMB, the third gate signal EM and the fifth gate signal EMB may be referred to as an emission control signal and the third gate line EML and the fifth gate line EMBL may be referred to as an emission control line. The pixel circuit PC may be electrically connected to a driving voltage line PL configured to transmit a driving voltage ELVDD, a reference voltage line VRL configured to transmit a reference voltage Vref, and a first initialization voltage line VAL configured to transmit a first initialization voltage Vaint.

In one or more embodiments, some of a plurality of transistors included in the pixel circuit PC may be N-type transistors and the others may be P-type transistors. The first to fourth transistors T1, T2, T3, and T4 may be N-type transistors, and the fifth and sixth transistors T5 and T6 may be P-type transistors. The semiconductor layers of the first to fourth transistors T1, T2, T3, and T4 may include a different material than the semiconductor layers of the fifth and sixth transistors T5 and T6. In one or more embodiments, the first to fourth transistors T1, T2, T3, and T4 may include a semiconductor layer including an oxide, and the fifth and sixth transistors T5 and T6 may include amorphous silicon, polysilicon, and/or an organic semiconductor.

The pixel circuit PC may include first to sixth transistors T1, T2, T3, T4, T5, and T6, first and second capacitors C1 and C2, and an auxiliary capacitor Ca. The first transistor T1 may be a driving transistor outputting a driving current corresponding to the data signal DATA, and the second to sixth transistors T2, T3, T4, T5, and T6 may be switching transistors configured to transmit signals. A first terminal (or a first electrode) and a second terminal (or a second electrode) of each of the first to sixth transistors T1, T2, T3, T4, T5, and T6 may be a source (or a source electrode) or a drain (or a drain electrode) depending on the voltages of the first terminal and the second terminal. For example, depending on the voltages of the first terminal and the second terminal, the first terminal may be a drain and the second terminal may be a source, or the first terminal may be a source and the second terminal may be a drain. Hereinafter, a node to which a first-1 gate electrode (e.g., or a first-1 gate) of the first transistor T1 is connected may be defined as a first node N1, and a node to which a second terminal of the first transistor T1 is connected may be defined as a second node N2.

The first transistor T1 may be connected to the driving voltage line PL and the light emitting diode LED. The first transistor T1 may be connected between the fifth transistor T5 and the sixth transistor T6. The first transistor T1 may include a first gate (or a first gate electrode including the first-1 gate and a first-2 gate), a first terminal, and a second terminal connected to the second node N2. The first transistor T1 may include the first-1 gate connected to the first node N1. The first transistor T1 may further include a first-2 gate connected to the second terminal thereof (or the second node N2). The first-1 gate and the first-2 gate may be arranged on different layers to face each other. For example, the first-1 gate and the first-2 gate of the first transistor T1 may face each other with a semiconductor layer between them. Herein, the first gate (or the first gate electrode) of the first transistor T1 may refer to the first-1 gate (or the first-1 gate electrode) involved in turning on and off the first transistor T1.

The gate (or the first-1 gate) of the first transistor T1 may be connected to the second terminal of the second transistor T2, the first terminal of the third transistor T3, and the first capacitor C1. The first-2 gate of the first transistor T1 may be connected to the first terminal of the sixth transistor T6, the first capacitor C1, and the second capacitor C2. The first terminal of the first transistor T1 may be connected to the driving voltage line PL via the fifth transistor T5, and the second terminal thereof may be connected to the pixel electrode of the light emitting diode LED via the sixth transistor T6. The first terminal of the first transistor T1 may be connected to the second terminal of the fifth transistor T5. The second terminal of the first transistor T1 may be connected to the first terminal of the sixth transistor T6, the first capacitor C1, and the second capacitor C2. The first transistor T1 may receive a data signal DATA according to a switching operation of the second transistor T2 to control the amount of a driving current flowing through the light emitting diode LED.

The second transistor T2 may be connected to the data line DL and the gate of the first transistor T1. The second transistor T2 may include a gate connected to the first gate line GWL, a first terminal connected to the data line DL, and a second terminal connected to the first node N1. The second terminal of the second transistor T2 may be connected to the gate of the first transistor T1, the first terminal of the third transistor T3, and the first capacitor C1. The second transistor T2 may be turned on by the first gate signal GW received through the first gate line GWL, to electrically connect the data line DL with the first node N1 and transmit the data signal DATA received through the data line DL, to the first node N1.

The third transistor T3 may be connected to the gate of the first transistor T1 and the reference voltage line VRL. The third transistor T3 may include a gate connected to the second gate line GRL, a first terminal connected to the first node N1, and a second terminal connected to the reference voltage line VRL. The first terminal of the third transistor T3 may be connected to the gate of the first transistor T1, the second terminal of the second transistor T2, and the first capacitor C1. The third transistor T3 may be turned on by the second gate signal GR received through the second gate line GRL, to transmit the reference voltage Vref received through the reference voltage line VRL, to the first node N1.

The fourth transistor T4 may be connected to the sixth transistor T6 and the first initialization voltage line VAL. The fourth transistor T4 may be connected to the light emitting diode LED and the first initialization voltage line VAL. The fourth transistor T4 may include a gate connected to the fourth gate line GIL, a first terminal connected to a third node N3, and a second terminal connected to the first initialization voltage line VAL. The first terminal of the fourth transistor T4 may be connected to the second terminal of the sixth transistor T6 and the pixel electrode of the light emitting diode LED. The fourth transistor T4 may be turned on by the fourth gate signal GI received through the fourth gate line GIL, to transmit the first initialization voltage Vaint received through the first initialization voltage line VAL, to the third node N3 and initialize the pixel electrode (e.g., the anode) of the light emitting diode LED.

The fifth transistor T5 may be connected to the driving voltage line PL and the first transistor T1. The fifth transistor T5 may include a gate connected to the third gate line EML, a first terminal connected to the driving voltage line PL, and a second terminal connected to the first terminal of the first transistor T1. The fifth transistor T5 may be turned on or off according to the third gate signal EM received through the third gate line EML.

The sixth transistor T6 may be connected to the first transistor T1 and the light emitting diode LED. The sixth transistor T6 may be connected between the second node N2 and the third node N3. The sixth transistor T6 may include a gate connected to the fifth gate line EMBL, a first terminal connected to the second node N2, and a second terminal connected to the third node N3. The first terminal of the sixth transistor T6 may be connected to the second terminal of the first transistor T1, the first capacitor C1, and the second capacitor C2. The second terminal of the sixth transistor T6 may be connected to the first terminal of the fourth transistor T4 and the pixel electrode of the light emitting diode LED. The sixth transistor T6 may be turned on or off according to the fifth gate signal EMB received through the fifth gate line EMBL.

The first capacitor C1 may be connected between the gate of the first transistor T1 and the second terminal of the first transistor T1. The first electrode of the first capacitor C1 may be connected to the first node N1, and the second electrode thereof may be connected to the second node N2. The first electrode of the first capacitor C1 may be connected to the gate of the first transistor T1, the second terminal of the second transistor T2, and the first terminal of the third transistor T3. The second electrode of the first capacitor C1 may be connected to the second terminal and the first-2 gate of the first transistor T1, the second electrode of the second capacitor C2, and the first terminal of the sixth transistor T6. The first capacitor C1 may be a storage capacitor and may store a threshold voltage of the first transistor T1 and a voltage corresponding to the data signal DATA.

The first transistor T1 may be turned on when the third transistor T3 and the fifth transistor T5 are turned on. When the voltage of the second terminal of the first transistor T1 drops to the difference (Vref−Vth1) between the reference voltage Vref and the threshold voltage (Vth1) of the first transistor T1, the first transistor T1 may be turned off and a voltage corresponding to the threshold voltage (Vth1) of the first transistor T1 may be stored in the first capacitor C1 and thus the threshold voltage (Vth1) of the first transistor T1 may be compensated.

The second capacitor C2 may be connected between the driving voltage line PL and the second node N2. The first electrode of the second capacitor C2 may be connected to the driving voltage line PL. The second electrode of the second capacitor C2 may be connected to the second terminal and the first-2 gate of the first transistor T1, the second electrode of the first capacitor C1, and the first terminal of the sixth transistor T6.

The capacitance of each of the first capacitor C1 and the second capacitor C2 may vary depending on the color of light emitted from the light emitting diode LED.

The auxiliary capacitor Ca may be electrically connected to the sixth transistor T6, a sustain voltage line VSSL, and the pixel electrode of the light emitting diode LED. The auxiliary capacitor Ca may store and maintain a voltage corresponding to the voltage difference between the pixel electrode of the light emitting diode LED and the sustain voltage line VSSL, thereby preventing the problem of the black luminance increasing when the sixth transistor T6 is turned off.

The light emitting diode LED may be connected to the first transistor T1 through the sixth transistor T6. The light emitting diode LED may include a pixel electrode (e.g., the anode) connected to the third node N3 and an opposite electrode (e.g., cathode) facing the pixel electrode, and the opposite electrode may receive a common voltage ELVSS. In one or more embodiments, the opposite electrode (e.g., cathode) may extend into the display area and thus may be electrically connected to the sustain voltage line VSSL configured to provide the common voltage ELVSS. The driving current output by the first transistor T1 may flow through the light emitting diode LED due to the turned-on fifth transistor T5 and the turned-on sixth transistor T6, and the light emitting diode LED may emit light with a brightness corresponding to the driving current.

Although FIG. 3 illustrates that the pixel circuit PC includes sixth transistors, the present disclosure is not limited thereto. In one or more other embodiments, the number of transistors in the pixel circuit PC may be 5 or less or 7 or more.

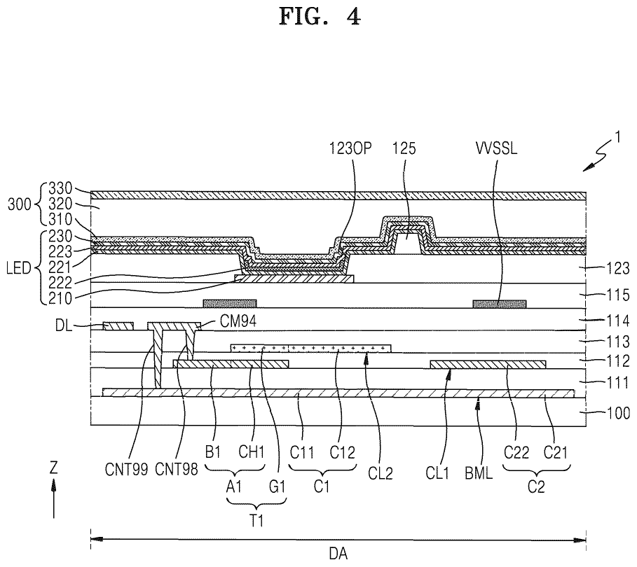

FIG. 4 is a cross-sectional view schematically showing a part of a display device 1 according to one or more embodiments.

Referring to FIG. 4, the display device 1 may include a light emitting diode LED arranged in a display area DA. The light emitting diode LED may be disposed over a substrate 100, and a pixel circuit PC may be arranged between the substrate 100 and the light emitting diode LED. In one or more embodiments, FIG. 4 illustrates a first transistor T1, a first capacitor C1, and a second capacitor C2 as some components of the pixel circuit PC.

The substrate 100 may include a glass material and/or a polymer resin. In one or more embodiments, the substrate 100 may have an alternating stack structure of a base layer including a polymer resin and a barrier layer including an inorganic insulating material such as silicon oxide and/or silicon nitride The polymer resin may include a polymer resin such as polyether sulfone, polyarylate, polyether imide, polyethylene naphthalate, polyethylene terephthalate, polyphenylene sulfide, polyimide, polycarbonate, cellulose triacetate, and/or cellulose acetate propionate.

A bottom metal layer BML may be disposed over the substrate 100. The bottom metal layer BML may function as a first electrode C11 of the first capacitor C1 and a first electrode C21 of the second capacitor C2. That is, the bottom metal layer BML may include the first electrode C11 of the first capacitor C1 and the first electrode C21 of the second capacitor C2. The first electrode C11 of the first capacitor C1 and the first electrode C21 of the second capacitor C2 may be disposed over the substrate 100.

In one or more embodiments, a first-11 gate line GWL1-1, a first-21 gate line GWL2-1, a reference voltage line VRL, a driving voltage line PL, a horizontal sustain voltage line HVSSL, a first-11 initialization horizontal voltage line HVAL(R)1, and a first-2 initialization horizontal voltage line HVAL(GB) may be additionally disposed over the substrate 100.

The bottom metal layer (BML) may include one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the bottom metal layer BML may be a single layer of molybdenum, have a bilayer structure in which a molybdenum layer and a titanium layer are laminated, or have a tri-layer structure in which a titanium layer, an aluminum layer, and a titanium layer are laminated.

The first-11 gate line GWL1-1, the first-21 gate line GWL2-1, the reference voltage line VRL, the driving voltage line PL, the horizontal sustain voltage line HVSSL, the first-11 initialization horizontal voltage line HVAL(R)1, and the first-2 initialization horizontal voltage line HVAL(GB) may include the same material as the bottom metal layer BML.

A first insulating layer 111 may be disposed over the substrate 100 to cover the bottom metal layer BML. The first insulating layer 111 may be disposed over the first electrode C11 of the first capacitor C1 and the first electrode C21 of the second capacitor C2. The first insulating layer 111 may include an inorganic insulating material such as silicon oxide, silicon nitride, or silicon oxynitride and may include a single-layer or multiple-layer structure including the inorganic insulating material. A semiconductor layer and a first conductive layer CL1 may be disposed over the first insulating layer 111.

The semiconductor layer may be disposed over the first insulating layer 111. In this regard, FIG. 4 illustrates that a first semiconductor layer A1 of the first transistor T1 is disposed over the first insulating layer 111. The first semiconductor layer A1 may include a channel area CH1 and doped areas arranged on both sides of the channel area CH1, and in this regard, FIG. 4 illustrates a first area B1 that is one of the doped areas arranged on one side of the channel area CH1.

The first semiconductor layer A1 may include an oxide of indium (In), gallium (Ga), stannum (Sn), zirconium (Zr), vanadium (V), hafnium (Hf), cadmium (Cd), germanium (Ge), chromium (Cr), titanium (Ti), aluminum (Al), cesium (Cs), cerium (Ce), and/or zinc (Zn). For example, the first semiconductor layer A1 may include an InSnZnO (ITZO) semiconductor layer and/or an InGaZnO (IGZO) semiconductor layer. A conductive (or conduction) process based on, for example, plasma treatment may be performed on at least a portion of the first semiconductor layer A1.

The first conductive layer CL1 may be disposed over the first insulating layer 111. The first conductive layer CL1 may function as a second electrode C22 of the second capacitor C2. That is, the first conductive layer CL1 may include the second electrode C22 of the second capacitor C2. The second electrode C22 of the second capacitor C2 may be disposed over the first insulating layer 111.

The first conductive layer CL1 may include one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the first conductive layer CL1 may be a single layer of molybdenum, may have a bilayer structure in which a molybdenum layer and a titanium layer are stacked, or may have a tri-layer structure in which a titanium layer, an aluminum layer, and a titanium layer are stacked.

A second insulating layer 112 may be disposed over the first insulating layer 111 to cover the first semiconductor layer A1 and the first conductive layer CL1. The second insulating layer 112 may be disposed over the first semiconductor layer A1 of the first transistor T1 and the second electrode C22 of the second capacitor C2. The second insulating layer 112 may include an inorganic insulating material such as silicon oxide, silicon nitride, or silicon oxynitride and may include a single-layer or multiple-layer structure including the inorganic insulating material.

A second conductive layer CL2 may be disposed over the second insulating layer 112. The second conductive layer CL2 may function as a first gate electrode G1 of the first transistor T1 and a second electrode C12 of the first capacitor C1. That is, the second conductive layer CL2 may include the first gate electrode G1 of the first transistor T1 and the second electrode C12 of the first capacitor C1. The first gate electrode G1 of the first transistor T1 and the second electrode C12 of the first capacitor C1 may be disposed over the second insulating layer 112. The first gate electrode G1 of the first transistor T1 may overlap the channel area CH1 of the first semiconductor layer A1 of the first transistor T1 with the second insulating layer 112 between them.

In one or more embodiments, a first-12 gate line GWL1-2, a first-22 gate line GWL2-2, a second gate line GRL, a third gate line EML, a fourth gate line GIL, a fifth gate line EMBL, and a first-12 initialization horizontal voltage line HVAL(R)2 may be additionally disposed over the second insulating layer 112.

The second conductive layer CL2 may include one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the second conductive layer CL2 may be a single layer of molybdenum, may have a bilayer structure in which a molybdenum layer and a titanium layer are stacked, or may have a tri-layer structure in which a titanium layer, an aluminum layer, and a titanium layer are stacked.

The first-12 gate line GWL1-2, the first-22 gate line GWL2-2, the second gate line GRL, the third gate line EML, the fourth gate line GIL, the fifth gate line EMBL, and the first-12 initialization horizontal voltage line HVAL(R)2 may include the same material as the second conductive layer CL2.

A third insulating layer 113 may be disposed over the second insulating layer 112 to cover the second conductive layer CL2. The third insulating layer 113 may be disposed over the first gate electrode G1 of the first transistor T1 and the second electrode C12 of the first capacitor C1. The third insulating layer 113 may include an inorganic insulating material such as silicon oxide, silicon nitride, and/or silicon oxynitride and may include a single-layer or multiple-layer structure including the inorganic insulating material.

A data line DL and a 94th connection electrode CM94 may be disposed over the third insulating layer 113. The 94th connection electrode CM94 may be connected to the first semiconductor layer A1 of the first transistor T1 through a 98th contact hole CNT98. The 94th connection electrode CM94 may be connected to the bottom metal layer BML through a 99th contact hole CNT99. That is, the 94th connection electrode CM94 may be connected to each of the first transistor T1 and the bottom metal layer BML.

In one or more embodiments, a plurality of connection electrodes may be disposed over the third insulating layer 113 in addition to the 94th connection electrode CM94.

The data line DL and the 94th connection electrode CM94 may include one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the data line DL and the 94th connection electrode CM94 may be a single layer of molybdenum, may have a bilayer structure in which a molybdenum layer and a titanium layer are stacked, or may have a tri-layer structure in which a titanium layer, an aluminum layer, and a titanium layer are stacked.

The plurality of connection electrodes not illustrated in FIG. 4 may include the same material as the data line DL and the 94th connection electrode CM94.

A fourth insulating layer 114 may be disposed over the third insulating layer 113 to cover the data line DL and the 94th connection electrode CM94. The fourth insulating layer 114 may be disposed over the data line DL and the 94th connection electrode CM94. The fourth insulating layer 114 may include an organic insulating material such as acryl, benzocyclobutene (BCB), polyimide, and/or hexamethyldisiloxane (HMDSO).

A vertical sustain voltage line VVSSL may be disposed over the fourth insulation layer 114.

In one or more embodiments, a first-1 initialization vertical voltage line VVAL(R) and a first-2 initialization vertical voltage line VVAL(GB) may be additionally disposed over the fourth insulation layer 114.

The vertical sustain voltage line VVSSL may include one or more materials from among aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and/or copper (Cu). In one or more embodiments, the vertical sustain voltage line VVSSL may be a single layer of molybdenum, may have a bilayer structure in which a molybdenum layer and a titanium layer are stacked, or may have a tri-layer structure in which a titanium layer, an aluminum layer, and a titanium layer are stacked.

The first-1 initialization vertical voltage line VVAL(R) and the first-2 initialization vertical voltage line VVAL(GB) may include the same material as the vertical sustain voltage line VVSSL.

A fifth insulating layer 115 may be disposed over the fourth insulating layer 114 to cover the vertical sustain voltage line VVSSL. The fifth insulating layer 115 may be disposed over the vertical sustain voltage line VVSSL. The fifth insulating layer 115 may include an organic insulating material such as acryl, benzocyclobutene (BCB), polyimide, and/or hexamethyldisiloxane (HMDSO).

The light emitting diode LED may be disposed on the fifth insulating layer 115 and may include a pixel electrode 210, an emission layer 222, and an opposite electrode 230.

The pixel electrode 210 may be disposed over the fifth insulating layer 115. The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), and/or any compound thereof. In one or more embodiments, the pixel electrode 210 may further include a conductive oxide layer over and/or under the reflective layer. The conductive oxide layer may include indium tin oxide (ITO), indium zinc oxide (IZO), zinc oxide (ZnO), indium oxide (In₂O₃), indium gallium oxide (IGO), and/or aluminum zinc oxide (AZO). In one or more embodiments, the pixel electrode 210 may have a three-layer structure of ITO layer/Ag layer/ITO layer.

A bank layer 123 may be disposed on the fifth insulating layer 115 to partially cover the ends of the pixel electrode 210. The bank layer 123 may include an opening 123OP overlapping the pixel electrode 210 and may cover the edge of the pixel electrode 210. The bank layer 123 may include an organic insulating material. In one or more embodiments, the bank layer 123 may include a light-transmitting organic insulator. In one or more other embodiments, the bank layer 123 may include an organic insulating material including a light blocking material. In one or more embodiments, the bank layer 123 may include a polyimide (PI)-based binder and a pigment in which red, green, and blue colors are mixed. Alternatively, the bank layer 123 may include a cardo-based binder resin and a mixture of lactam-based black pigment and/or blue pigment. Alternatively, the bank layer 123 may include a carbon black. The bank layer 123 may improve the contrast of a display panel.

A spacer 125 may be disposed over the bank layer 123. The spacer 125 may include a different material than the bank layer 123. For example, the bank layer 123 and the spacer 125 may include different materials (e.g., the bank layer 123 may include a negative photosensitive material and the spacer 125 may include a positive photosensitive material) and may be respectively formed through separate mask processes. In one or more embodiments, the spacer 125 may include the same material as the bank layer 123 and may be formed together in the same mask process (e.g., a halftone mask process).

The emission layer 222 may include a high-molecular weight or low-molecular weight organic material for emitting light of a certain color. The emission layer 222 may include a material for emitting red light, green light, or blue light, depending on the light emitting diode LED.

A functional layer may be further included under and/or over the emission layer 222. For example, a first functional layer 221 may be further included between the pixel electrode 210 and the emission layer 222, and a second functional layer 223 may be further included between the emission layer 222 and the opposite electrode 230 described below. The first functional layer 221 may include a hole transport layer and/or a hole injection layer. The second functional layer 223 may include an electron transport layer and/or an electron injection layer.

The opposite electrode 230 may include a conductive material having a low work function. For example, the opposite electrode 230 may include a (semi) transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), and/or any alloy thereof. Alternatively, the opposite electrode 230 may further include a layer such as ITO, IZO, ZnO, and/or In₂O₃ over the (semi) transparent layer including the above material.

Unlike pixel electrodes 210 separately formed to correspond to light emitting diodes LED, the opposite electrode 230 may extend to correspond to the pixel electrodes 210. For example, a pixel electrode 210 of a light emitting diode LED and a pixel electrode 210 of another light emitting diode LED may be separated and spaced (e.g., spaced apart) from each other, but the opposite electrode 230 overlapping the pixel electrodes 210 may extend to cover the pixel electrodes 210 described above.

An encapsulation layer 300 may be disposed over the light emitting diode LED and may include at least one inorganic encapsulation layer and at least one organic encapsulation layer. In one or more embodiments, as illustrated in FIG. 4, the encapsulation layer 300 includes a first inorganic encapsulation layer 310, an organic encapsulation layer 320, and a second inorganic encapsulation layer 330.

The first inorganic encapsulation layer 310 and the second inorganic encapsulation layer 330 may include one or more inorganic insulating materials from among aluminum oxide, titanium oxide, tantalum oxide, hafnium oxide, zinc oxide, silicon oxide, silicon nitride, and/or silicon oxynitride. The first inorganic encapsulation layer 310 and the second inorganic encapsulation layer 330 may include a single layer or multiple layers including the above material. The organic encapsulation layer 320 may include a polymer-based material. The polymer-based material may include acryl-based resin, epoxy-based resin, polyimide, polyethylene, and/or the like. In one or more embodiments, the organic encapsulation layer 320 may include acrylate. In one or more embodiments, the organic encapsulating layer 320 may include acrylate.

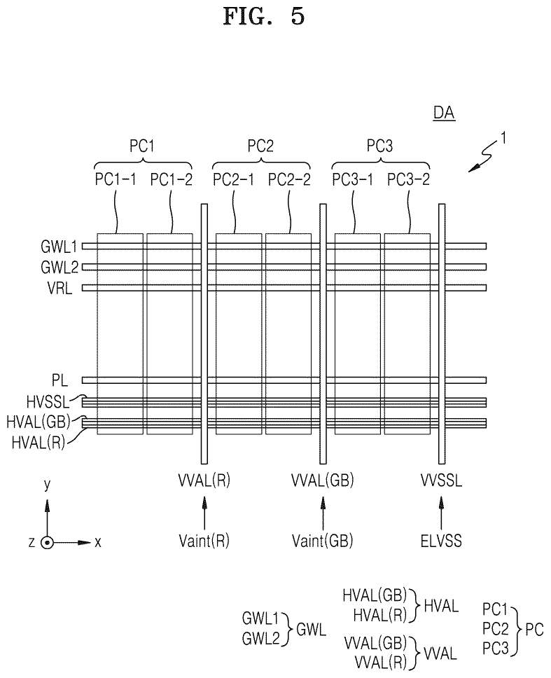

FIG. 4 is a cross-sectional view schematically showing a part of the display device 1, so some of the components shown in FIG. 3 are omitted. A detailed description of the components of the display device 1 will be described later with reference to FIGS. 5-12.

FIG. 5 is a plan view schematically illustrating a portion of wires arranged in the display area DA of the display device 1 according to one or more embodiments.

Pixel circuits PCs may be arranged along a first direction (e.g., +x-axis direction and/or −x-axis direction) and a second direction (e.g., +y-axis direction and/or −y-axis direction) in the display area DA, and FIG. 5 illustrates pixel circuits PCs arranged in the same row, e.g., the i-th row.

Each pixel circuit PC may be electrically connected to a light-emitting diode. Hereinafter, for convenience of explanation, pixel circuits PC electrically connected to each of first to third light-emitting diodes emitting light of different colors are described as first to third pixel circuits PC1, PC2, PC3.

The first pixel circuit PC1, the second pixel circuit PC2, and the third pixel circuit PC3 may be sequentially arranged along the first direction (e.g., the +x-axis direction). Additionally, the first light-emitting diode, the second light-emitting diode, and the third light-emitting diode may be sequentially arranged along the first direction (e.g., the +x-axis direction).

The first pixel circuit PC1 may be electrically connected to a first light-emitting diode that emits light of a first color. The first pixel circuit PC1 may include a first-1 pixel circuit PC1-1 and the first-2 pixel circuit PC1-2 sequentially arranged along the first direction (e.g., +x-axis direction). The first light-emitting diode may include a first-1 light-emitting diode and a first-2 light-emitting diode that are sequentially arranged along the first direction (e.g., the +x-axis direction). The first-1 pixel circuit PC1-1 may be electrically connected to the first-1 light-emitting diode, and the first-2 pixel circuit PC1-2 may be electrically connected to the first-2 light-emitting diode. The first-1 light-emitting diode and the first-2 light-emitting diode may each emit light of a first color. That is, the first-1 light-emitting diode and the first-2 light-emitting diode may emit light of the same color.

The second pixel circuit PC2 may be electrically connected to the second light-emitting diode that emits light of a second color. The second pixel circuit PC2 may be electrically connected to the second light-emitting diode that emits light of a second color. The second pixel circuit PC2 may include a second-1 pixel circuit PC2-1 and a second-2 pixel circuit PC2-2 sequentially arranged along the first direction (e.g., +x-axis direction). The second light-emitting diode may include a second-1 light-emitting diode and a second-2 light-emitting diode that are sequentially arranged along the first direction (e.g., the +x-axis direction). The second-1 pixel circuit PC2-1 may be electrically connected to the second-1 light-emitting diode, and the second-2 pixel circuit PC2-2 may be electrically connected to the second-2 light-emitting diode. The second-1 light-emitting diode and the second-2 light-emitting diode may each emit light of a second color. That is, the second-1 light-emitting diode and the second-2 light-emitting diode may emit light of the same color.

The third pixel circuit PC3 may be electrically connected to the third light-emitting diode that emits light of a third color. The third pixel circuit PC3 may be electrically connected to the third light-emitting diode that emits light of the third color. The third pixel circuit PC3 may include a third-1 pixel circuit PC3-1 and a third-2 pixel circuit PC3-2 sequentially arranged along the first direction (e.g., +x-axis direction). The third light-emitting diode may include a third-1 light-emitting diode and a third-2 light-emitting diode sequentially arranged along the first direction (e.g., the +x-axis direction). The third-1 pixel circuit PC3-1 may be electrically connected to the third-1 light-emitting diode, and the third-2 pixel circuit PC3-2 may be electrically connected to the third-2 light-emitting diode. The third-1 light-emitting diode and the third-2 light-emitting diode may each emit light of a third color. That is, the third-1 light-emitting diode and the third-2 light-emitting diode may emit light of the same color.

In one or more embodiments, the first color, the second color, and the third color are different colors of light, and may be selected from red, green, and blue. The first light-emitting diode, the second light-emitting diode, and the third light-emitting diode may emit light of different colors. For example, the first color may be red, the second color may be green, and the third color may be blue.

The first to third pixel circuits PC1, PC2, PC3 may be repeatedly arranged along the first direction (e.g., +x-axis direction and/or −x-axis direction). The first pixel circuit PC1, the second pixel circuit PC2, and the third pixel circuit PC3 may be arranged in an order along the first direction (e.g., +x-axis direction and/or −x-axis direction).

In the display area DA, lines electrically connected to pixel circuits PCs, for example, first conductive lines (hereinafter referred to as horizontal conductive lines) extending along the first direction (e.g., +x-axis direction and/or −x-axis direction) and second conductive lines (hereinafter referred to as vertical conductive lines) extending along the second direction (e.g., +y-axis direction and/or −y-axis direction) may be arranged.

The horizontal conductive lines extending along the first direction (e.g., +x-axis direction and/or −x-axis direction) may include a first-1 gate line GWL1, a first-2 gate line GWL2, a reference voltage line VRL, a driving voltage line PL, a horizontal maintenance voltage line HVSSL, and a first initialization horizontal voltage line HVAL. Specifically, the first gate line GWL may include the first-1 gate line GWL1 and the first-2 gate line GWL2. Additionally, the first initialization horizontal voltage line HVAL may include a first-1 initialization horizontal voltage line HVAL(R), and a first-2 initialization horizontal voltage line HVAL(GB).

The vertical conductive lines extending along the second direction (e.g., +y-axis direction and/or −y-axis direction) may include a first initialization vertical voltage line VVAL and a vertical sustain voltage line VVSSL. Specifically, the first initialization vertical voltage line VVAL may include a first-1 initialization vertical voltage line VVAL(R) and a first-2 initialization vertical voltage line VVAL(GB).

The first-1 initialization vertical voltage line VVAL(R) and the first-1 initialization horizontal voltage line HVAL(R) that provide a first-1 initialization voltage Vaint(R) to the first-1 pixel circuit PC1 may be electrically connected in the display area DA.

The first-2 initialization vertical voltage line VVAL(GB) and the first-2 initialization horizontal voltage line HVAL(GB) that provide a first-3 initialization voltage Vaint(GB) to the second pixel circuit PC2 and the third pixel circuit PC3 may be electrically connected in the display area DA.

The vertical voltage line VVSSL and the horizontal voltage line HVSSL may be electrically connected in the display area DA. At this time, the vertical sustain voltage line VVSSL may be electrically connected to the common voltage ELVSS.

FIG. 5 illustrates that the second pixel circuit PC2 and the third pixel circuit PC3 are electrically connected to the same voltage line, for example, the first-second initialization vertical voltage line VVAL(GB) and/or the first-second initialization horizontal voltage line HVAL(GB), but the present disclosure is not limited thereto. As one or more other embodiments, the horizontal and vertical voltage lines for applying the first initialization voltage to the second pixel circuit PC2 and the horizontal and vertical voltage lines for applying the first initialization voltage to the third pixel circuit PC3 may each exist independently.

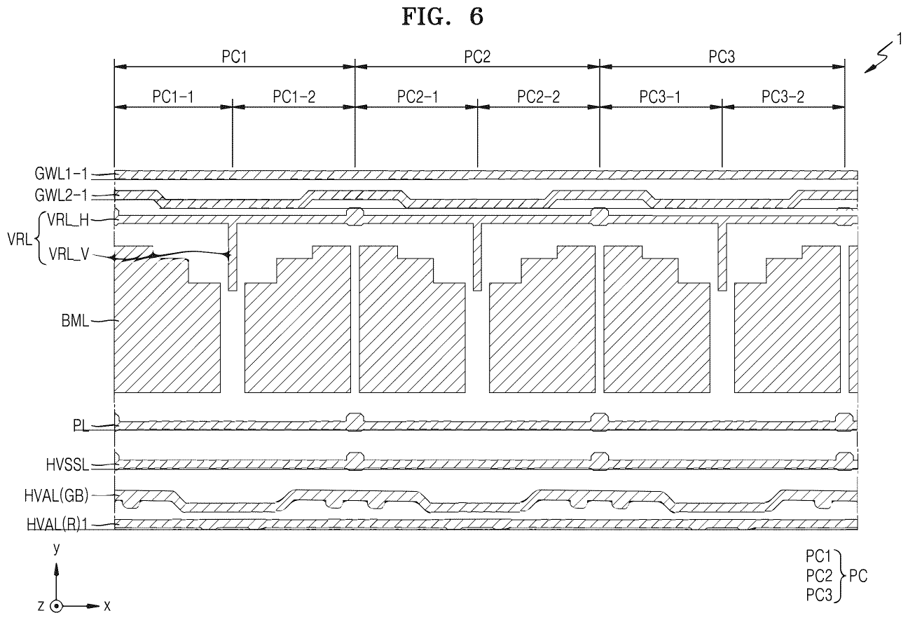

FIGS. 6-12 are plan views showing a process of forming the pixel circuit PC included in the display device 1 according to one or more embodiments.

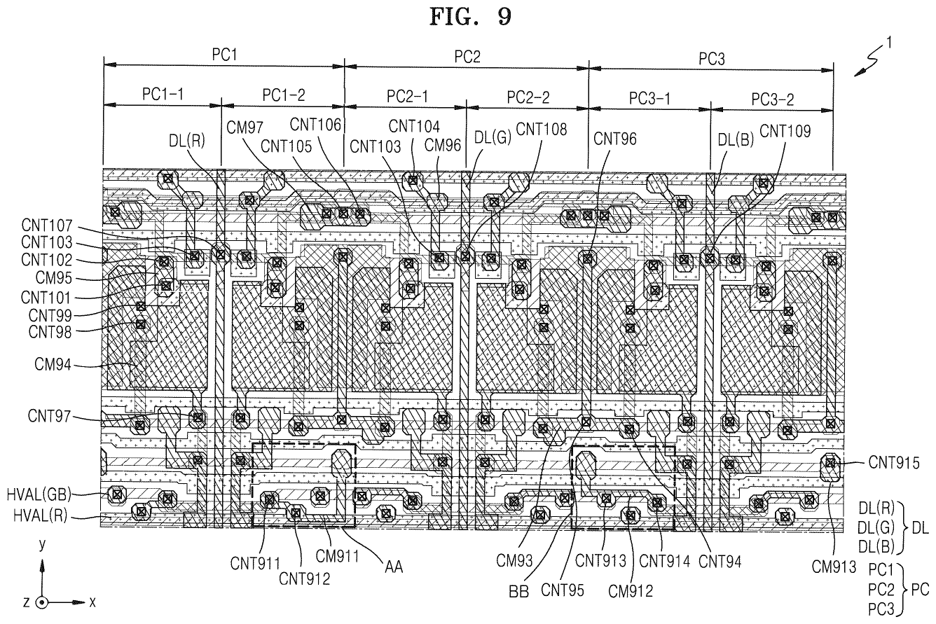

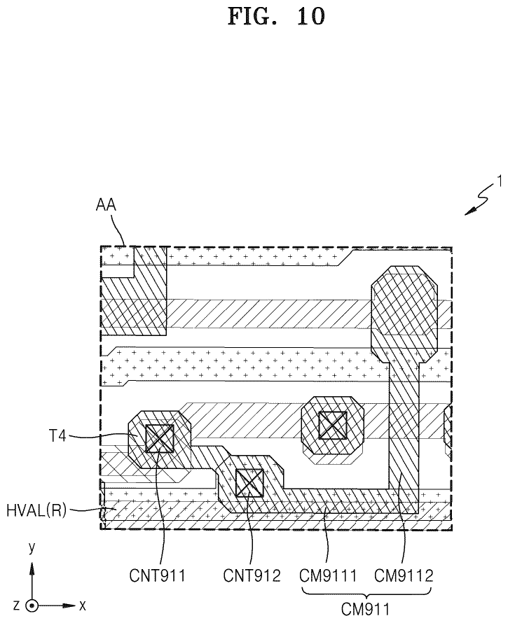

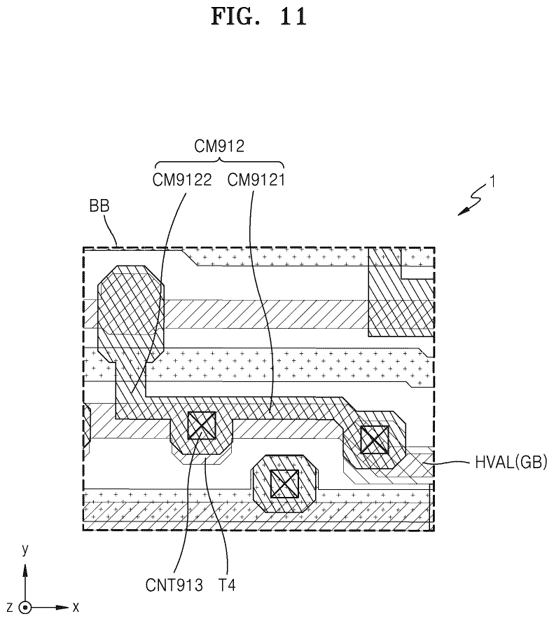

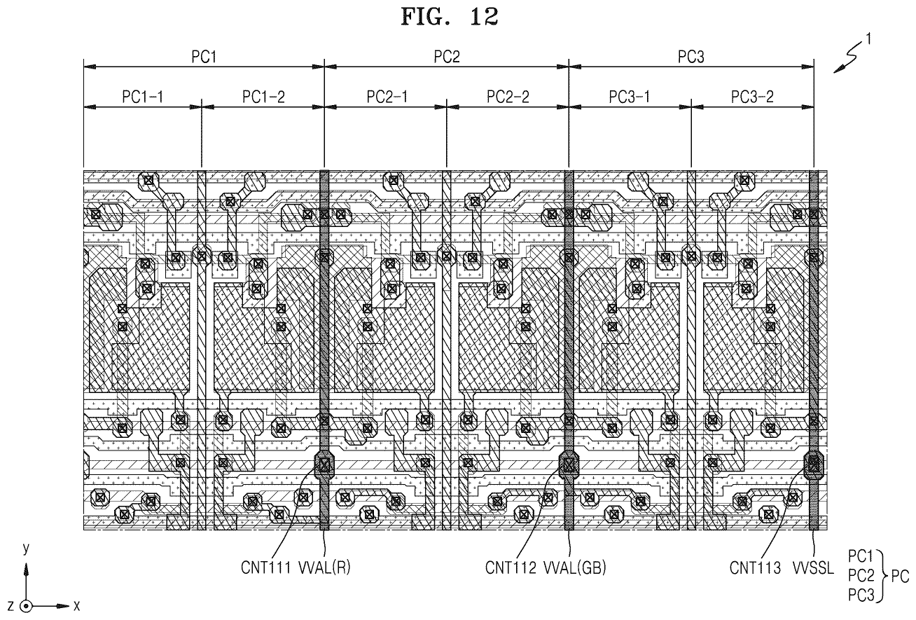

Specifically, FIG. 10 is an enlarged view of portion AA of FIG. 9, and FIG. 11 is an enlarged view of portion BB of FIG. 9. FIG. 12 may correspond to a planar structure of the pixel circuit PC of the display device 1 described with reference to FIG. 4.

Referring to FIGS. 4 and 6, the first-11 gate line GWL1-1, the first-21 gate line GWL2-1, the reference voltage line VRL, the bottom metal layer BML, the driving voltage line PL, the horizontal maintenance voltage line HVSSL, the first-11 initialization horizontal voltage line HVAL(R)1, and the first-2 initialization horizontal voltage line HVAL(GB) may be arranged on the substrate 100.

The first-11 gate line GWL1-1, the first-21 gate line GWL2-1, the reference voltage line VRL, the driving voltage line PL, the horizontal maintenance voltage line HVSSL, the first-11 initialization horizontal voltage line HVAL(R)1, and the first-2 initialization horizontal voltage line HVAL(GB) may extend in the first direction (e.g., in the +x-axis direction and/or the −x-axis direction) so as to cross the first pixel circuit PC1, the second pixel circuit PC2, and the third pixel circuit PC3.

The first-11 initialization horizontal voltage line HVAL(R)1, the first-2 initialization horizontal voltage line HVAL(GB), the horizontal maintenance voltage line HVSSL, the driving voltage line PL, the bottom metal layer BML, the reference voltage line VRL, the first-21 gate line GWL2-1, and the first-11 gate line GWL1-1 may be arranged in (or at) the same layer, but may be arranged sequentially so as to be spaced (e.g., spaced apart) from each other along the second direction (for example, the +y-axis direction).

The bottom metal layer BML may be provided in multiple numbers to correspond to the number of pixel circuits PC. For example, as illustrated in FIG. 6, the six bottom metal layers BMLs may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2, respectively. Multiple bottom metal layers BMLs may be arranged in an island shape so as to be spaced (e.g., spaced apart) from each other. The bottom metal layer BML may have an isolated shape.

The reference voltage line VRL may include a horizontal reference voltage line VRL_H extending in the first direction (e.g., in the +x-axis direction and/or the −x-axis direction) and a vertical reference voltage line VRL_V protruding from the horizontal reference voltage line VRL_H in the second direction (e.g., in the +y-axis direction and/or the −y-axis direction). The vertical reference voltage line VRL_V may be placed at the boundary between the first-1 pixel circuit PC1-1 and the first-2 pixel circuit PC1-2. In other words, the first-1 pixel circuit PC1-1 and the first-2 pixel circuit PC1-2 may be arranged with the vertical reference voltage line VRL_V between them and may have symmetrical structures with respect to the vertical reference voltage line VRL_V. The vertical reference voltage line VRL_V may be placed at a boundary between the second-1 pixel circuit PC2-1 and the second-2 pixel circuit PC2-2. In other words, the second-1 pixel circuit PC2-1 and the second-2 pixel circuit PC2-2 may be arranged with the vertical reference voltage line VRL_V between them and may have symmetrical structures with respect to the vertical reference voltage line VRL_V. The vertical reference voltage line VRL_V may be placed at a boundary between the third-1 pixel circuit PC3-1 and the third-2 pixel circuit PC3-2. In other words, the third-1 pixel circuit PC3-1 and the third-2 pixel circuit PC3-1 may be arranged with the vertical reference voltage line VRL_V between them and may have symmetrical structures with respect to the vertical reference voltage line VRL_V.

In the structure illustrated in FIG. 6, for example, the first insulating layer 111 may be arranged on the first-11 gate line GWL1-1, the first-21 gate line GWL2-1, the reference voltage line VRL, the bottom metal layer BML, the driving voltage line PL, the first-11 initialization horizontal voltage line HVAL(R)1, and the first-2 initialization horizontal voltage line HVAL(GB). In one or more embodiments, in the structure illustrated in FIG. 6, for example, the first insulating layer 111 may also be arranged on the horizontal maintenance voltage line HVSSL.

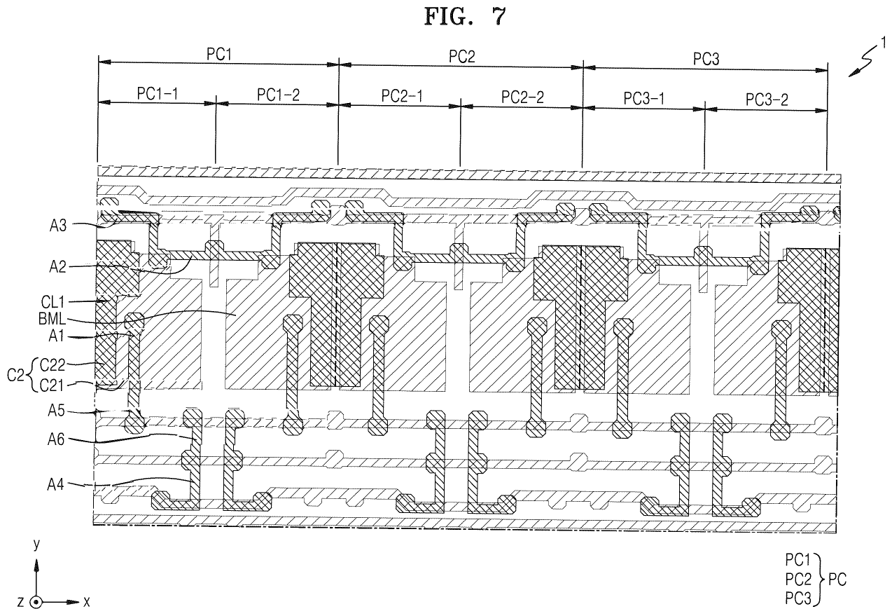

Referring to FIG. 4 and FIG. 7, first to sixth semiconductor layers A1, A2, A3, A4, A5, A6 and a first conductive layer CL1 may be arranged on the first insulating layer 111. The first to sixth semiconductor layers (A1, A2, A3, A4, A5, A6) may contain the same material.

The first semiconductor layer A1 and the fifth semiconductor layer A5 may be connected integrally. The second semiconductor layer A2 and the third semiconductor layer A3 may be connected integrally. The fourth semiconductor layer A4 and the sixth semiconductor layer A6 may be connected integrally. The first semiconductor layer A1 is arranged adjacent to the second semiconductor layer A2 and the third semiconductor layer A3, but may be separated and spaced (e.g., spaced apart) from each other. The fifth semiconductor layer A5 is arranged adjacent to the sixth semiconductor layer A6, but may be separated and spaced (e.g., spaced apart) from each other.

The first conductive layer CL1 may be arranged to overlap the bottom metal layer BML. At least a portion of the bottom metal layer BML overlapping the first conductive layer CL1 may be the first electrode C21 of the second capacitor C2. Additionally, at least a portion of the first conductive layer CL1 overlapping the bottom metal layer BML may be the second electrode C22 of the second capacitor C2. That is, the bottom metal layer BML may include the first electrode C21 of the second capacitor C2, and the first conductive layer CL1 may include the second electrode C22 of the second capacitor C2.

The first conductive layer CL1 may be provided in multiple numbers to correspond to the number of pixel circuits PC. For example, as illustrated in FIG. 7, the six first conductive layers CL1 may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2, respectively. The first conductive layer CL1 may be provided in an island shape so as to be spaced (e.g., spaced apart) from the first to sixth semiconductor layers A1, A2, A3, A4, A5, A6. The first conductive layer CL1 may have an isolated shape.

Accordingly, the second capacitor C2 may be provided in multiple numbers, each corresponding to the number of pixel circuits PC. For example, as illustrated in FIG. 7, the second capacitors C2 are provided in six units each, and may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2.

The first conductive layers CL1 arranged on two adjacent pixel circuits PC may be connected integrally. For example, the first conductive layers CL1 arranged in the first pixel circuit PC1 and the second pixel circuit PC2 may be connected integrally, and the first conductive layers CL1 arranged in the second pixel circuit PC2 and the third pixel circuit PC3 may be connected integrally.

In the structure illustrated in FIG. 7, for example, the second insulating layer 112 may be placed on the first to sixth semiconductor layers A1, A2, A3, A4, A5, A6 and the first conductive layer CL1.

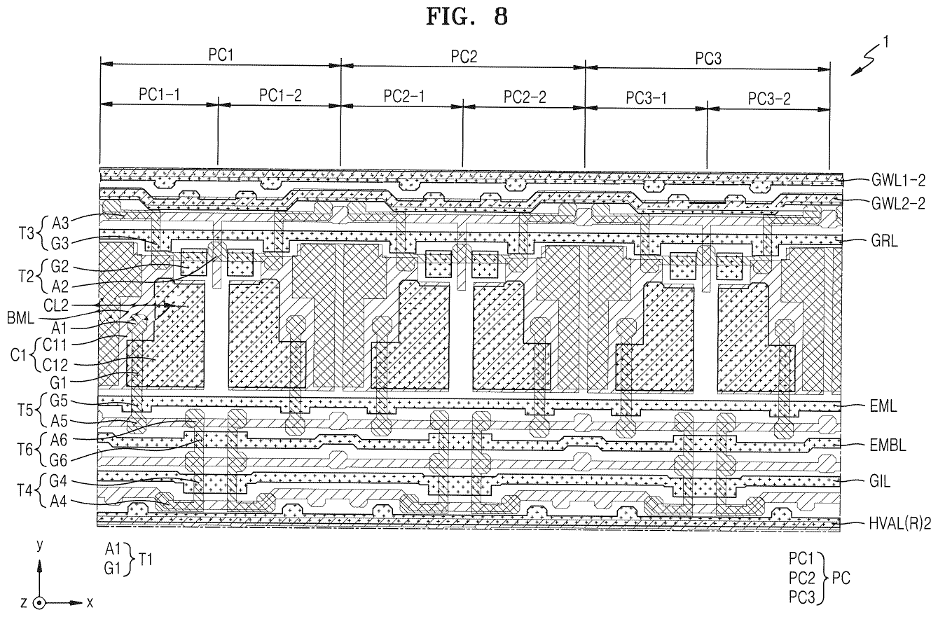

Referring to FIG. 4 and FIG. 8, the first-12 gate line GWL1-2, the first-22 gate line GWL2-2, the second gate line GRL, the third gate line EML, the fourth gate line GIL, the fifth gate line EMBL, the first-12 initialization horizontal voltage line HVAL(R)2, a second gate electrode G2, and a second conductive layer CL2 may be arranged on the second insulating layer 112.

The first-12 gate line GWL1-2, the first-22 gate line GWL2-2, the second gate line GRL, the third gate line EML, the fourth gate line GIL, the fifth gate line EMBL, and the first-12 initialization horizontal voltage line HVAL(R)2 may extend in the first direction (e.g., in the +x-axis direction and/or the −x-axis direction) so as to cross the first pixel circuit PC1, the second pixel circuit PC2, and the third pixel circuit PC3. The first-12 gate line GWL1-2, the first-22 gate line GWL2-2, the second gate line GRL, the second gate electrode G2, the second conductive layer CL2, the third gate line EML, the fifth gate line EMBL, the fourth gate line GIL, and the first-12 initialization horizontal voltage line HVAL(R)2 may be sequentially arranged to be spaced (e.g., spaced apart) from each other along the second direction (e.g., the −y-axis direction).

The second gate electrode G2 may be provided in multiple numbers to correspond to the number of pixel circuits PC. For example, as illustrated in FIG. 8, the six second gate electrodes G2 may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2, respectively. A plurality of second gate electrodes G2 may be provided in an island shape so as to be spaced (e.g., spaced apart) from each other. The plurality of second gate electrodes G2 may have an isolated shape.

The second conductive layer CL2 may be provided in multiple numbers to correspond to the number of pixel circuits PC. For example, as illustrated in FIG. 8, the six second conductive layers CL2 may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2, respectively. A plurality of second conductive layers CL2 may be arranged in an island shape so as to be spaced (e.g., spaced apart) from each other. The plurality of second conductive layers CL2 may have an isolated shape.

The first-12 gate line GWL1-2 may overlap the first-11 gate line GWL1-1 (See FIG. 6). The first-12 gate line GWL1-2 can be electrically connected to the first-11 gate line GWL1-1 (see FIG. 6). For example, in one or more embodiments, the first-12 gate line GWL1-2 and the first-11 gate line GWL1-1 (see FIG. 6) may be connected through contact holes at specified intervals. The first-11 gate line GWL1-1 (see FIG. 6) and the first-12 gate line GWL1-2 are referred to as the first-1 gate line GWL1 (see FIG. 5).

The first-22 gate line GWL2-2 may overlap the first-21 gate line GWL2-1 (see FIG. 6). The first-22 gate line GWL2-2 may be electrically connected to the first-21 gate line GWL2-1 (see FIG. 6). For example, in one or more embodiments, the first-22 gate line GWL2-2 and the first-21 gate line GWL2-1 (see FIG. 6) may be connected through contact holes at specified intervals. The first-21 gate line GWL2-1 (see FIG. 6) and the first-22 gate line GWL2-2 are referred to as the first-2 gate line GWL2 (see FIG. 5).

At least a portion of the second gate line GRL may overlap the third semiconductor layer A3. A portion of the second gate line GRL overlapping the third semiconductor layer (A3) may be a third gate electrode G3. That is, the second gate line GRL may include a third gate electrode G3. The third semiconductor layer A3 and the third gate electrode G3 may form a third transistor T3. That is, the third transistor T3 may include the third semiconductor layer A3 and the third gate electrode G3.

The second gate electrode G2 may overlap the second semiconductor layer A2. The second semiconductor layer A2 and the second gate electrode G2 may form a second transistor T2. That is, the second transistor T2 may include the second semiconductor layer A2 and the second gate electrode G2.

At least a portion of the second conductive layer CL2 may overlap the first semiconductor layer A1. The portion of the second conductive layer CL2 overlapping the first semiconductor layer A1 may be a first gate electrode G1. That is, the second conductive layer CL2 may include the first gate electrode G1. The first semiconductor layer A1 and the first gate electrode G1 may form the first transistor T1. That is, the first transistor T1 may include the first semiconductor layer A1 and the first gate electrode G1.

At least a portion of the third gate line EML may overlap the fifth semiconductor layer A5. A portion of the third gate line EML overlapping the fifth semiconductor layer A5 may be a fifth gate electrode G5. That is, the third gate line EML may include the fifth gate electrode G5. The fifth semiconductor layer A5 and the fifth gate electrode G5 may form the fifth transistor T5. That is, the fifth transistor T5 may include the fifth semiconductor layer A5 and the fifth gate electrode G5.

At least a portion of the fifth gate line EMBL may overlap the sixth semiconductor layer A6. The portion of the fifth gate line EMBL overlapping the sixth semiconductor layer A6 may be a sixth gate electrode G6. That is, the fifth gate line EMBL may include the sixth gate electrode G6. The sixth semiconductor layer A6 and the sixth gate electrode G6 may form the sixth transistor T6. That is, the sixth transistor T6 may include the sixth semiconductor layer A6 and the sixth gate electrode G6.

At least a portion of the fourth gate line GIL may overlap the fourth semiconductor layer A4. A portion of the fourth gate line GIL overlapping the fourth semiconductor layer A4 may be a fourth gate electrode G4. That is, the fourth gate line GIL may include the fourth gate electrode G4. The fourth semiconductor layer A4 and the fourth gate electrode G4 may form the fourth transistor T4. That is, the fourth transistor T4 may include the fourth semiconductor layer A4 and the fourth gate electrode G4.

The first-12 initialization horizontal voltage line HVAL(R)2 may overlap with the first-11 initialization horizontal voltage line HVAL(R)1 (see FIG. 6). The first-12 initialization horizontal voltage line HVAL(R)2 may be electrically connected to the first-11 initialization horizontal voltage line HVAL(R)1 (see FIG. 6). For example, in one or more embodiments, the first-12 initialization horizontal voltage line HVAL(R)2 and the first-11 initialization horizontal voltage line HVAL(R)1 (see FIG. 6) may be connected through a contact hole in the non-display area NDA (see FIG. 1). The first-11 initialization horizontal voltage line HVAL(R)1 (see FIG. 6) and the first-12 initialization horizontal voltage line HVAL(R)2 are referred to as the first-1 initialization horizontal voltage line HVAL(R) (see FIG. 5).

The second conductive layer CL2 may be arranged to overlap the bottom metal layer BML. At least a portion of the bottom metal layer BML overlapping the second conductive layer CL2 may be the first electrode C11 of the first capacitor C1. Additionally, at least a portion of the second conductive layer CL2 overlapping the bottom metal layer BML may be the second electrode C12 of the first capacitor C1 (e.g., see FIG. 4). That is, the bottom metal layer BML may include the first electrode C11 of the first capacitor C1, and the second conductive layer CL2 may include the second electrode C12 of the first capacitor C1.

The first to sixth transistors T1, T2, T3, T4, T5, T6 and the first capacitor C1 may be provided in multiple numbers to correspond to the number of pixel circuits PC. For example, as illustrated in FIG. 6, the first to sixth transistors T1, T2, T3, T4, T5, T6 and the first capacitor C1 are provided in numbers of six each, and may correspond to the first-1 pixel circuit PC1-1, the first-2 pixel circuit PC1-2, the second-1 pixel circuit PC2-1, the second-2 pixel circuit PC2-2, the third-1 pixel circuit PC3-1, and the third-2 pixel circuit PC3-2.

The third insulating layer 113 may be disposed on the structure illustrated in FIG. 8, for example, the first-12 gate line GWL1-2, the first-22 gate line GWL2-2, the second gate line GRL, the third gate line EML, the fourth gate line GIL, the fifth gate line EMBL, the first-12 initialization horizontal voltage line HVAL(R)2, the second gate electrode G2, and the second conductive layer CL2.

Referring to FIGS. 4-9, a plurality of connection electrodes and data lines DL may be arranged on the third insulating layer 113.

A 93rd connecting electrode CM93 may contact the fifth semiconductor layer A5 of the fifth transistor T5 through a 94th contact hole CNT94. The 93rd connecting electrode CM93 may contact the driving voltage line PL through a 95th contact hole CNT95. The 93rd connecting electrode CM93 may contact the first conductive layer CL1 through a 96th contact hole CNT96. Therefore, the 93rd connecting electrode CM93 may electrically connect the fifth transistor T5, the driving voltage line PL, and the second electrode C22 of the second capacitor C2.

A 94th connecting electrode CM94 may contact the 6th semiconductor layer A6 of the 6th transistor T6 through a 97th contact hole CNT97. The 94th connecting electrode CM94 may contact the first semiconductor layer A1 of the first transistor T1 through a 98th contact hole CNT98. The 94th connecting electrode CM94 may contact the bottom metal layer BML through a 99th contact hole CNT99. Accordingly, the 94th connecting electrode CM94 may electrically connect the sixth transistor T6, the first transistor T1, the first electrode C11 of the first capacitor C1, and the first electrode C21 of the second capacitor C2.

A 95th connecting electrode CM95 may contact the second conductive layer CL2 through s 101st contact hole CNT101. The 95th connecting electrode CM95 may contact the second semiconductor layer A2 of the second transistor T2 and the third semiconductor layer A3 of the third transistor T3 through a 102nd contact hole CNT102. Accordingly, the 95th connecting electrode CM95 may electrically connect the first gate electrode G1 of the first transistor T1, the second electrode C12 of the first capacitor C1, the second transistor T2, and the third transistor T3.

A 96th connecting electrode CM96 may contact the second gate electrode G2 of the second transistor T2 through a 103rd contact hole CNT103. The 96th connecting electrode CM96 may contact the first-1 gate line GWL1 or the first-2 gate line GWL2 through a 104th contact hole CNT104. Therefore, the 96th connecting electrode CM96 may electrically connect the second transistor T2 and the first gate line GWL.

Specifically, when the first-1 gate line GWL1 is electrically connected to the first-1 pixel circuit PC1-1 to provide a signal, the first-2 gate line GWL2 may be electrically connected to the first-2 pixel circuit PC1-2 to provide a signal. When the first-1 gate line GWL1 is electrically connected to the second-1 pixel circuit PC2-1 to provide a signal, the first-2 gate line GWL2 may be electrically connected to the second-2 pixel circuit PC2-2 to provide a signal. In addition, when the first-1 gate line GWL1 is electrically connected to the third-2 pixel circuit PC3-2 to provide a signal, the first-2 gate line GWL2 may be electrically connected to the third-1 pixel circuit PC3-1 to provide a signal.

When a signal is applied from the first-1 gate line GWL1 to the first-1 pixel circuit PC1-1, a coupling capacitor may be primarily generated between the 94th connection electrode CM94 electrically connected to the first semiconductor layer A1 of the first transistor T1 of the first-1 pixel circuit PC1-1 and the 96th connection electrode CM96 electrically connected to the first-1 gate line GWL1 and arranged in the first-1 pixel circuit PC1-1 region. In addition, even when a signal is applied from the first-2 gate line GWL2 to the first-2 pixel circuit PC1-2 adjacent to the first-1 pixel circuit PC1-1 sequentially thereafter, a coupling capacitor may be secondarily generated between the 94th connection electrode CM94 electrically connected to the first semiconductor layer A1 of the first transistor T1 of the first-1 pixel circuit PC1-1 and the 96th connection electrode CM96 electrically connected to the first-2 gate line GWL2 and arranged in the first-2 pixel circuit PC1-2 region. The 94th connection electrode CM94 connected to the first transistor T1 of the first-1 pixel circuit PC 1-1 is connected to the first-1 gate line GWL1, and a coupling capacitor is generated between the 96th connection electrode CM96 arranged in an area of the first-1 pixel circuit PC1-1 and the 96th connection electrode CM96 connected to the first-2 gate line GWL2 and arranged in an area of the first-2 pixel circuit PC1-2, so that a node of a source of the first transistor T1 of the first-1 pixel circuit PC1-1 may shake, resulting in a luminance deviation.

In one or more embodiments, the vertical reference voltage line VRL_V protruding in the second direction (e.g., in the +y-axis direction and/or in the −y-axis direction) from the horizontal reference voltage line VRL_H extending in the first direction (e.g., in the +x-axis direction and/or in the −x-axis direction) may be arranged at a boundary between the first-1 pixel circuit PC1-1 and the first-2 pixel circuit PC1-2. In other words, the first-1 pixel circuit PC1-1 and the first-2 pixel circuit PC1-2 may be arranged with the vertical reference voltage line VRL_V between them. The vertical reference voltage line VRL_V is arranged between the first-1 pixel circuit PC1-1 and the first-2 pixel circuit PC1-2, and is connected to the 94th connection electrode CM94 connected to the first transistor T1 of the first-1 pixel circuit PC1-1 and the first-2 gate line GWL2, and may shield the 96th connection electrode CM96 arranged in the first-2 pixel circuit PC1-2 region.

Accordingly, when the first-2 gate line GWL2 is connected to the first-2 pixel circuit PC1-2 and a signal is applied, a coupling capacitor is prevented from being secondarily generated between the 94th connection electrode (CM94) connected to the first transistor T1 of the first-1 pixel circuit PC1-1 and the 96th connection electrode CM96 connected to the first-2 gate line GWL2 and arranged in the area of the first-2 pixel circuit PC1-2, thereby preventing the node of the source of the first transistor T1 of the first-1 pixel circuit PC1-1 from shaking, thereby improving the quality and brightness of the display device.

The influence of the coupling capacitor secondarily generated between the 94th connection electrode CM94 connected to the first transistor T1 of the first-1 pixel circuit PC1-1 and the 96th connection electrode CM96 connected to the first-2 gate line GWL2 and arranged in the first-2 pixel circuit PC1-2 region is greater than the influence of the coupling capacitor first generated between the 94th connection electrode CM94 electrically connected to the first semiconductor layer of the first transistor T1 of the first-1 pixel circuit PC1-1 and the 96th connection electrode CM96 electrically connected to the first-1 gate line GWL1 and arranged in the first-1 pixel circuit PC1-1 region. Therefore, by arranging the vertical reference voltage line VRL_V, the influence of the coupling capacitor secondarily generated is reduced, thereby reducing the influence of the coupling capacitor. By preventing the node of the source of the first transistor T1 of the first-1 pixel circuit PC1-1 from shaking, the quality and brightness of the display device can be improved.

When a signal is applied from the first-1 gate line GWL1 to the second-1 pixel circuit PC2-1, a coupling capacitor may be primarily generated between the 94th connection electrode CM94 electrically connected to the first semiconductor layer A1 of the first transistor T1 of the second-1 pixel circuit PC2-1 and the 96th connection electrode CM96 electrically connected to the first-1 gate line GWL1 and arranged in the second-1 pixel circuit PC2-1 region. In addition, even when a signal is applied from the first-2 gate line GWL2 to the second-2 pixel circuit PC2-2 adjacent to the second-1 pixel circuit PC2-1 sequentially thereafter, a coupling capacitor may be secondarily generated between the 94th connection electrode CM94 electrically connected to the first semiconductor layer A1 of the first transistor T1 of the second-1 pixel circuit PC2-1 and the 96th connection electrode CM96 electrically connected to the first-2 gate line GWL2 and arranged in the second-2 pixel circuit PC2-2 region. The 94th connection electrode CM94 connected to the first transistor T1 of the second-1 pixel circuit PC2-1 is connected to the first-1 gate line GWL1 and a coupling capacitor is generated between the 96th connection electrode CM96 arranged in an area of the second-1 pixel circuit PC2-1 and the 96th connection electrode CM96 connected to the first-2 gate line GWL2 and arranged in an area of the second-2 pixel circuit PC2-2, so that a node of a source of the first transistor T1 of the second-1 pixel circuit PC2-1 may shake, resulting in a luminance deviation.

In one or more embodiments, the vertical reference voltage line VRL_V protruding in the second direction (e.g., in the +y-axis direction and/or in the −y-axis direction) from the horizontal reference voltage line VRL_H extending in the first direction (e.g., in the +x-axis direction and/or in the −x-axis direction) may be arranged at a boundary between the second-1 pixel circuit PC2-1 and the second-2 pixel circuit PC2-2. In other words, the second-1 pixel circuit PC2-1 and the second-2 pixel circuit PC2-2 may be arranged with the vertical reference voltage line VRL_V between them. The vertical reference voltage line VRL_V is arranged between the second-1 pixel circuit PC2-1 and the second-2 pixel circuit PC2-2, and is connected to the 94th connection electrode CM94 connected to the first transistor T1 of the second-1 pixel circuit PC2-1 and the first-2 gate line GWL2, and may shield the 96th connection electrode CM96 arranged in the second-2 pixel circuit PC2-2 region.

Accordingly, when the first-2 gate line GWL2 is connected to the second-2 pixel circuit PC2-2 and a signal is applied, a coupling capacitor is prevented from being secondarily generated between the 94th connection electrode CM94 connected to the first transistor T1 of the second-1 pixel circuit PC2-1 and the 96th connection electrode CM96 connected to the first-2 gate line GWL2 and arranged in the second-2 pixel circuit PC2-2 area, thereby preventing a node of a source of the first transistor T1 of the second-1 pixel circuit PC2-1 from shaking, thereby improving the quality and brightness of the display device.

The influence of the secondarily generated coupling capacitor between the 94th connection electrode CM94 connected to the first transistor T1 of the second-1 pixel circuit PC2-1 and the 96th connection electrode CM96 connected to the first-2 gate line GWL2 and arranged in the second-2 pixel circuit PC2-2 region is greater than the influence of the firstly generated coupling capacitor between the 94th connection electrode CM94 electrically connected to the first semiconductor layer A1 of the first transistor T1 of the second-1 pixel circuit PC2-1 and the 96th connection electrode CM96 electrically connected to the first-1 gate line GWL1 and arranged in the second-1 pixel circuit PC2-1 region. Therefore, by arranging the vertical reference voltage line VRL_V, the influence of the secondarily generated coupling capacitor is reduced, thereby preventing the node of the source of the first transistor T1 of the second-1 pixel circuit PC2-1 from shaking, the quality and brightness of the display device may be improved.

When a signal is applied from the first-2 gate line GWL2 to the third-1 pixel circuit PC3-1, a coupling capacitor may be primarily generated between the 94th connection electrode CM94 electrically connected to the first semiconductor layer A1 of the first transistor T1 of the third-1 pixel circuit PC3-1 and the 96th connection electrode CM96 electrically connected to the first-2 gate line GWL2 and arranged in the third-1 pixel circuit PC3-1 region. In addition, even when a signal is sequentially applied from the first-1 gate line GWL1 to the third-2 pixel circuit PC3-2 adjacent to the third-1 pixel circuit PC3-1 thereafter, a coupling capacitor may be secondarily generated between the 94th connection electrode CM94 electrically connected to the first semiconductor layer A1 of the first transistor T1 of the third-1 pixel circuit PC3-1 and the 96th connection electrode CM96 electrically connected to the first-1 gate line GWL1 and arranged in the third-2 pixel circuit PC3-2 region. The 94th connection electrode CM94 connected to the first transistor T1 of the third-1st pixel circuit PC3-1 is connected to the first-2 gate line GWL2, and a coupling capacitor is generated between the 96th connection electrode CM96 arranged in the third-1 pixel circuit PC3-1 region and the 96th connection electrode CM96 connected to the first-1 gate line GWL1 and arranged in the third-2 pixel circuit PC3-2 region, so that the node of the source of the first transistor T1 of the third-1 pixel circuit PC3-1 may shake, resulting in a luminance deviation.

In one or more embodiments, the vertical reference voltage line VRL_V protruding in the second direction (e.g., in the +y-axis direction and/or in the −y-axis direction) from the horizontal reference voltage line VRL_H extending in the first direction (e.g., in the +x-axis direction and/or in the −x-axis direction) may be arranged at a boundary between the third-1 pixel circuit PC3-1 and the third-2 pixel circuit PC3-2. In other words, the third-1 pixel circuit PC3-1 and the third-2 pixel circuit PC3-2 may be arranged with the vertical reference voltage line VRL_V between them. The vertical reference voltage line VRL_V is arranged between the third pixel circuit PC3-1 and the third-2 pixel circuit PC3-2, and can shield the 94th connection electrode CM94 connected to the first transistor T1 of the third-1 pixel circuit PC3-1 and the 96th connection electrode CM96 connected to the first-1 gate line GWL1 and arranged in the third-2 pixel circuit PC3-2 region.

Accordingly, when the first-1 gate line GWL1 is connected to the third-2 pixel circuit PC3-2 and a signal is applied, a coupling capacitor is prevented from being secondarily generated between the 94th connection electrode CM94 connected to the first transistor T1 of the third-1 pixel circuit PC3-1 and the 96th connection electrode CM96 connected to the first-1 gate line GWL1 and arranged in the area of the third-2 pixel circuit PC3-2, thereby preventing the node of the source of the first transistor T1 of the third-1 pixel circuit PC3-1 from shaking, thereby improving the quality and brightness of the display device.

The influence of the coupling capacitor secondarily generated between the 94th connection electrode CM94 connected to the first transistor T1 of the third-1 pixel circuit PC3-1 and the 96th connection electrode CM96 connected to the first-1 gate line GWL1 and arranged in the third-2 pixel circuit PC3-2 region is greater than the influence of the coupling capacitor first generated between the 94th connection electrode CM94 electrically connected to the first semiconductor layer A1 of the first transistor T1 of the third-1 pixel circuit PC3-1 and the 96th connection electrode CM96 electrically connected to the first-2 gate line GWL2 and arranged in the third-1 pixel circuit PC3-1 region. Therefore, by arranging the vertical reference voltage line VRL_V, the influence of the coupling capacitor secondarily generated is reduced, thereby reducing the influence of the coupling capacitor of the third-1 pixel circuit PC3-1. By preventing the node of the source of the first transistor T1 from shaking, the quality and brightness of the display device can be improved.

A 97th connecting electrode CM97 may contact the reference voltage line VRL through a 105th contact hole CNT105. The 97th connection electrode CM97 may contact the semiconductor layer of the third transistor T3 through a 106th contact hole CNT106. Therefore, the 97th connecting electrode CM97 may electrically connect the reference voltage line VRL and the third transistor T3.

Referring to FIGS. 9 and 10, a first connection electrode CM911 may contact the fourth semiconductor layer A4 of the fourth transistor T4 of the first pixel circuit PC1 (e.g., the first-second pixel circuit PC1-2) through a first-1 contact hole CNT911. The first-1 contact hole CNT911 may penetrate the second insulating layer 112 and the third insulating layer 113. The first connecting electrode CM911 may contact the first-1 initialization horizontal voltage line HVAL(R) through a first-2 contact hole CNT912. The first-2 contact hole CNT912 may penetrate the third insulating layer 113. Accordingly, by the first connection electrode CM911, the first-1 initialization horizontal voltage line HVAL(R) may be electrically connected to the 4th transistor T4 of the first pixel circuit PC1 (e.g., the first-2 pixel circuit PC1-2). The first connecting electrode CM911 may be provided in an island shape so as to be spaced (e.g., spaced apart) from other connecting electrodes arranged on the same layer. The first connecting electrode CM911 may have an isolated shape.

The first connecting electrode CM911 may include a first-1 connecting electrode portion CM9111 and a first-2 connecting electrode portion CM9112. The first-1 connection electrode portion CM9111 extends in a first direction (e.g., in the +x-axis direction and/or the −x-axis direction) and may be electrically connected to each of the fourth transistor T4 of the first pixel circuit PC1 (e.g., the first-2 pixel circuit PC1-2) and the first-1 initialization horizontal voltage line HVAL(R). The first-2 connecting electrode portion CM9112 may extend in a second direction (e.g., in the +y-axis direction) from the end of the first-1 connecting electrode CM9111. At least a portion of the first-2 connection electrode portion CM9112 may be arranged at a boundary between the first pixel circuit PC1 (e.g., the first-second pixel circuit PC1-2) and the second pixel circuit PC2 (e.g., the second-1 pixel circuit PC2-1).

Referring to FIGS. 9 and 11, a second connection electrode CM912 can contact the fourth semiconductor layer A4 of the fourth transistor T4 of the third pixel circuit PC3 (e.g., the third-1 pixel circuit PC3-1) through the second-1 contact hole CNT913. The second-1 contact hole CNT913 may penetrate the second insulating layer 112 and the third insulating layer 113. The second connecting electrode CM912 may contact the first-2 initialization horizontal voltage line HVAL(GB) through a second-2 contact hole CNT914. The second-2 contact hole CNT914 may penetrate the third insulating layer 113. Accordingly, by the second connecting electrode CM912, the first-2 initialization horizontal voltage line HVAL(GB) may be electrically connected to the 4th transistor T4 of the third pixel circuit PC3 (e.g., the third-1 pixel circuit PC3-1). The second connecting electrode CM912 may be provided in an island shape so as to be spaced (e.g., spaced apart) from other connecting electrodes arranged on the same layer. The second connecting electrode CM912 may have an isolated shape.

The second connecting electrode CM912 may include a second-1 connecting electrode portion CM9121 and a second-2 connecting electrode portion CM9122. The second-1 connecting electrode portion CM9121 extends in the first direction (e.g., in the +x-axis direction and/or the −x-axis direction) and may be electrically connected to each of the fourth transistor T4 of the third pixel circuit PC3 (e.g., the third-1 pixel circuit PC3-1) and the first-2 initialization horizontal voltage line HVAL(GB). The second-2 connecting electrode portion CM9122 may extend in the second direction (e.g., in the +y-axis direction) from the end of the second-1 connecting electrode CM9121. At least a portion of the second-2 connecting electrode portion CM9122 may be arranged at a boundary between the second pixel circuit PC2 (e.g., the second-2 pixel circuit PC2-2) and the third pixel circuit PC3 (e.g., the third-1 pixel circuit PC3-1).

Referring again to FIG. 9, a third connecting electrode CM913 may contact the horizontal maintenance voltage line HVSSL through a third contact hole CNT915. At least a portion of the second connecting electrode CM912 may overlap the horizontal voltage line HVSSL. The third contact hole CNT915 may penetrate the first insulating layer 111, the second insulating layer 112, and the third insulating layer 113. The third connecting electrode CM913 may be provided in an island shape so as to be spaced (e.g., spaced apart) from other connecting electrodes arranged in (e.g., at) the same layer. The third connecting electrode CM913 may have an isolated shape.

The data line DL extends in the second direction (e.g., in the +y-axis direction and/or the −y-axis direction) and may be electrically connected to the second semiconductor layer A2 of the second transistor T2. The data line DL may include a first data line DL(R), a second data line DL(G), and a third data line DL(B). The first data line DL(R), the second data line DL(G), and the third data line DL(B) may be arranged to overlap the vertical reference voltage line VRL_V.

The first data line DL(R) may be placed in the first pixel circuit PC1. Specifically, the first data line DL(R) may be placed at the boundary between the first-1 pixel circuit PC1-1 and the first-2 pixel circuit PC1-2. In other words, the first-1 pixel circuit PC1-1 and the first-2 pixel circuit PC1-2 may be arranged with the first data line DL(R) between them. The first data line DL(R) may be electrically connected to the semiconductor layer of the second transistor T2 of the first pixel circuit PC1 through a 107th contact hole CNT107. Specifically, the first data line DL(R) may be electrically connected to the semiconductor layer of the second transistor T2 of each of the first-1 pixel circuit PC1-1 and the first-2 pixel circuit PC1-2 through the 107th contact hole CNT107.

The second data line DL(G) may be placed in the second pixel circuit PC2. Specifically, the second data line DL(G) may be placed at a boundary between the second-1 pixel circuit PC2-1 and the second-2 pixel circuit PC2-2. In other words, the second-1 pixel circuit PC2-1 and the second-2 pixel circuit PC2-2 may be arranged with the second data line DL(G) interposed therebetween. The second data line DL(G) may be electrically connected to the semiconductor layer of the second transistor T2 of the second pixel circuit PC2 through the 108th contact hole. Specifically, the second data line DL(G) may be electrically connected to the semiconductor layer of the second transistor T2 of each of the second-1 pixel circuit PC2-1 and the second-2 pixel circuit PC2-2 through a 108th contact hole CNT108.

The third data line DL(B) may be placed in the third pixel circuit PC3. Specifically, the third data line DL(B) may be placed at a boundary between the third-1 pixel circuit PC3-1 and the third-2 pixel circuit PC3-2. In other words, the third-1 pixel circuit PC3-1 and the third-2 pixel circuit PC3-2 may be arranged with the third data line DL(B) between them. The third data line DL(B) may be electrically connected to the semiconductor layer of the second transistor T2 of the third pixel circuit PC3 through a 109th contact hole. Specifically, the third data line DL(B) may be electrically connected to the semiconductor layer of the second transistor T2 of each of the third-1 pixel circuit PC3-1 and the third-2 pixel circuit PC3-2 through the 109th contact hole.

In the structure illustrated in FIG. 9, for example, the fourth insulating layer 114 may be placed on a plurality of connecting electrodes and data lines DL.

Referring to FIG. 4 and FIGS. 9-12, the first-1 initialization vertical voltage line VVAL(R), the first-2 initialization vertical voltage line VVAL(GB) and the vertical maintenance voltage line VVSSL may be arranged on the fourth insulating layer 114.

The first-1 initialization vertical voltage line VVAL(R), the first-2 initialization vertical voltage line VVAL(GB), and the vertical sustaining voltage line VVSSL may extend in the second direction (e.g., in the +y-axis direction and/or the −y-axis direction). The first-1 initialization vertical voltage line VVAL(R), the first-2 initialization vertical voltage line VVAL(GB), and the vertical maintenance voltage line VVSSL may be arranged sequentially on (e.g., at) the same layer, but spaced (e.g., spaced apart) from each other along the first direction (e.g., +x-axis direction).

The first-1 initialization vertical voltage line VVAL(R) may be electrically connected to the first-1 initialization horizontal voltage line HVAL(R). The first initialization vertical voltage line VVAL(R) may be connected to the first connection electrode CM911 through a 111th contact hole CNT111. The 111th contact hole CNT111 may penetrate the fourth insulating layer 114. The first connecting electrode CM911 may electrically connect the first-1 initialization horizontal voltage line HVAL(R) and the first-1 initialization vertical voltage line VVAL(R). The first-1 initialization horizontal voltage line HVAL(R), the first-1 initialization vertical voltage line VVAL(R), and the first connection electrode CM911 may be arranged in different layers.

Specifically, the first-2 connection electrode portion CM9112 may be electrically connected to the first-1 initialization vertical voltage line VVAL(R). The first-1 initialization vertical voltage line VVAL(R) may be arranged at the boundary between the first pixel circuit PC1 (e.g., the first-2 pixel circuit PC1-2) and the second pixel circuit PC2 (e.g., the second-1 pixel circuit PC2-1). At least a portion of the first-2 connection electrode portion CM9112 may overlap the first-1 initialization vertical voltage line VVAL(R).

The first-2 initialization vertical voltage line VVAL(GB) may be electrically connected to the first-2 initialization horizontal voltage line HVAL(GB). The first-2 initialization vertical voltage line VVAL(GB) may be connected to the second connection electrode CM912 through a 112th contact hole CNT112. The 112th contact hole CNT112 may penetrate the fourth insulating layer 114. The second connecting electrode CM912 may electrically connect the first-2 initialization horizontal voltage line HVAL(GB) and the first-2 initialization vertical voltage line VVAL(GB). The first-2 initialization horizontal voltage line HVAL(GB), the first-2 initialization vertical voltage line VVAL(GB) and the second connection electrode CM912 may be arranged in different layers.

Specifically, the second-2 connection electrode portion CM9122 may be electrically connected to the first-2 initialization vertical voltage line VVAL(GB). The first-2 initialization vertical voltage line VVAL(GB) may be arranged at a boundary between the second pixel circuit PC2 (e.g., the second-2 pixel circuit PC2-2) and the third pixel circuit PC3 (e.g., the third-1 pixel circuit PC3-1). At least a portion of the second-2 connecting electrode portion CM9122 may overlap the first-2 initialization vertical voltage line VVAL(GB).

The vertical voltage line VVSSL may be electrically connected to the horizontal voltage line HVSSL. The vertical sustain voltage line VVSSL may be connected to the third connecting electrode CM913 through a 113th contact hole CNT113. The 113th contact hole CNT113 may penetrate the fourth insulating layer 114. The third connecting electrode CM913 may electrically connect the vertical sustaining voltage line VVSSL and the horizontal sustaining voltage line HVSSL. At least a portion of the third connecting electrode CM913 may overlap the vertical sustaining voltage line VVSSL. The horizontal sustaining voltage line HVSSL, the vertical sustaining voltage line VVSSL and the third connecting electrode CM913 may be arranged in different layers.

In one or more embodiments, the vertical reference voltage line VRL_V protruding in the second direction (e.g., in the +y-axis direction and/or the −y-axis direction) from the horizontal reference voltage line VRL_H extending in the first direction (e.g., in the +x-axis direction and/or the −x-axis direction) is disposed between the first-1 pixel circuit PC1-1 and the first-2 pixel circuit PC1-2, so as to shield the 94th connection electrode CM94 connected to the first transistor T1 of the first-1 pixel circuit PC1-1 and the 96th connection electrode CM96 connected to the first-2 gate line GWL2 and disposed in the region of the first-2 pixel circuit PC1-2. Accordingly, when the first-2 gate line GWL2 is connected to the second-2 pixel circuit PC2-2 and a signal is applied, the coupling capacitor may be prevented from being generated between the 94th connection electrode CM94 connected to the first transistor T1 of the first-1 pixel circuit PC1-1 and the 96th connection electrode CM96 connected to the first-2 gate line GWL2 and arranged in the area of the first-2 pixel circuit PC1-2, thereby preventing the node of the source of the first transistor T1 of the first-1 pixel circuit PC1-1 from shaking, thereby improving the quality and brightness of the display device.

According to one or more embodiments described above, a display device with improved reliability and quality may be implemented. Of course, the scope of the present disclosure is not limited by these embodiments.

Although the present disclosure has been described with reference to the embodiments shown in the drawings, these are merely discussed as examples, and those skilled in the art will understand that various modifications and equivalent other embodiments are possible therefrom. Therefore, the technical scope of the present disclosure may be determined by the technical idea of the claims and their equivalents.

What is claimed is:

1. A display device comprising:
a first pixel circuit comprising a first-1 pixel circuit and a first-2 pixel circuit arranged along a first direction on a substrate;
a first-1 gate line extending in the first direction and electrically connected to the first-1 pixel circuit;
a first-2 gate line extending in the first direction and electrically connected to the first-2 pixel circuit; and
a reference voltage line comprising a horizontal reference voltage line extending in the first direction and a vertical reference voltage line protruding, from the horizontal reference voltage line, in a second direction intersecting the first direction,
wherein the first-1 pixel circuit and the first-2 pixel circuit are arranged with the vertical reference voltage line interposed therebetween.

2. The display device of claim 1, further comprising a first light-emitting diode electrically connected to the first pixel circuit.

3. The display device of claim 2, wherein the first light-emitting diode arranged along the first direction and comprising a first-1 light-emitting diode electrically connected to the first-1 pixel circuit and a first-2 light-emitting diode electrically connected to the first-2 pixel circuit.

4. The display device of claim 3, wherein the first-1 light-emitting diode and the first-2 light-emitting diode are configured to emit light of a same color.

5. The display device of claim 1, further comprising a first data line on the substrate, extending in the second direction, and overlapping the vertical reference voltage line.

6. The display device of claim 5, wherein the first-1 pixel circuit and the first-2 pixel circuit are arranged with the first data line interposed therebetween.

7. The display device of claim 2, further comprising a second pixel circuit arranged adjacent to the first pixel circuit in the first direction and comprising a second-1 pixel circuit and a second-2 pixel circuit arranged along the first direction,
wherein the second-1 pixel circuit and the second-2 pixel circuit are arranged with the vertical reference voltage line interposed therebetween.

8. The display device of claim 7, wherein:
the first-1 gate line is electrically connected to the second-1 pixel circuit; and
the first-2 gate line is electrically connected to the second-2 pixel circuit.

9. The display device of claim 7, further comprising a second light-emitting diode electrically connected to the second pixel circuit.

10. The display device of claim 9, wherein the first light-emitting diode and the second light-emitting diode are configured to emit light of different colors.

11. The display device of claim 9, wherein the second light-emitting diode is arranged along the first direction and comprises a second-1 light-emitting diode electrically connected to the second-1 pixel circuit and a second-2 light-emitting diode electrically connected to the second-2 pixel circuit.

12. The display device of claim 11, wherein the second-1 light-emitting diode and the second-2 light-emitting diode are configured to emit light of a same color.

13. The display device of claim 7, further comprising a second data line on the substrate, extending in the second direction, and overlapping the vertical reference voltage line.

14. The display device of claim 13, wherein the second-1 pixel circuit and the second-2 pixel circuit are arranged with the second data line interposed therebetween.

15. The display device of claim 9, further comprising a third pixel circuit arranged adjacent to the second pixel circuit in the first direction and comprising a third-1 pixel circuit and a third-2 pixel circuit arranged along the first direction,
wherein the third-1 pixel circuit and the third-2 pixel circuit are arranged with the vertical reference voltage line interposed therebetween.

16. The display device of claim 15, wherein:
the first-1 gate line is electrically connected to the third-2 pixel circuit; and
the first-2 gate line is electrically connected to the third-1 pixel circuit.

17. The display device of claim 15, further comprising a third light-emitting diode electrically connected to the third pixel circuit,
wherein the third light-emitting diode is arranged along the first direction and comprises a third-1 light-emitting diode electrically connected to the third-1 pixel circuit and a third-2 light-emitting diode electrically connected to the third-2 pixel circuit.

18. The display device of claim 17, wherein the third-1 light-emitting diode and the third-2 light-emitting diode are configured to emit light of a same color.

19. The display device of claim 17, wherein the first light-emitting diode, the second light-emitting diode, and the third light-emitting diode are configured to emit light of different colors.

20. The display device of claim 15, further comprising a third data line on the substrate, extending in the second direction, and overlapping the vertical reference voltage line,
wherein the third-1 pixel circuit and the third-2 pixel circuit are arranged with the third data line interposed therebetween.

21. An electronic device comprising a display device, the display device comprising:
a first pixel circuit comprising a first-1 pixel circuit and a first-2 pixel circuit arranged along a first direction on a substrate;
a first-1 gate line extending in the first direction and electrically connected to the first-1 pixel circuit;
a first-2 gate line extending in the first direction and electrically connected to the first-2 pixel circuit; and
a reference voltage line comprising a horizontal reference voltage line extending in the first direction and a vertical reference voltage line protruding, from the horizontal reference voltage line, in a second direction intersecting the first direction,
wherein the first-1 pixel circuit and the first-2 pixel circuit are arranged with the vertical reference voltage line interposed therebetween.
